(19) United States
(12) Patent Application Publication
(10) Pub. No.: US 2024/0429679 A1
(43) Pub. Date: Dec. 26, 2024

(54) LASER APPARATUS, METHOD FOR CONTROLLING WAVELENGTH OF LASER LIGHT FROM LASER APPARATUS, AND METHOD FOR MANUFACTURING ELECTRONIC DEVICES

(71) Applicant: Gigaphoton Inc., Tochigi (JP)

(72) Inventors: Seiji NOGIWA, Oyama-shi (JP); Osamu WAKABAYASHI, Oyama-shi (JP)

(73) Assignee: Gigaphoton Inc., Tochigi (JP)

(21) Appl. No.: 18/827,321

(22) Filed: Sep. 6, 2024

Related U.S. Application Data
(63) Continuation of application No. PCT/JP2022/017922, filed on Apr. 15, 2022.

(51) Int. Cl. H01S 5/0625; H01S 5/00; H01S 5/06; H01S 5/125

(52) U.S. Cl. CPC H01S 5/06256; H01S 5/0057; H01S 5/0085; H01S 5/0092; H01S 5/0612; H01S 5/125

(57) ABSTRACT

A laser apparatus includes a first wavelength variable semiconductor laser that outputs first continuous-wave laser light; a first amplifier that pulses and amplifies the first laser light and outputs first pulse laser light; a wavelength conversion system that converts a wavelength of the first pulse laser light and outputs second pulse laser light; an excimer amplifier that amplifies the second pulse laser light and outputs third pulse laser light; a monitor module that measures a wavelength of the third pulse laser light; and a processor that periodically changes a target wavelength of the third pulse laser light and controls a current for changing the wavelength of the laser light from the first semiconductor laser such that the wavelength of the third pulse laser light becomes the target wavelength based on a measured value of the wavelength of the third pulse laser light output at the same target wavelength.

### CROSS-REFERENCE TO RELATED APPLICATIONS

The present application is a continuation application of International Application No. PCT/JP2022/017922, filed on Apr. 15, 2022, the entire contents of which are hereby incorporated by reference.

### BACKGROUND

### 1. Technical Field

The present disclosure relates to a laser apparatus, a method for controlling the wavelength of laser light from the laser apparatus, and a method for manufacturing electronic devices.

### 2. Related Art

In recent years, a semiconductor exposure apparatus is required to improve the resolution thereof as semiconductor integrated circuits are increasingly miniaturized and highly integrated. To this end, reduction in the wavelength of light output from a light source for exposure is underway. For example, a KrF excimer laser apparatus, which outputs laser light having a wavelength of about 248 nm, and an ArF excimer laser apparatus, which outputs laser light having a wavelength of about 193 nm, are used as a gas laser apparatus for exposure.

The light from spontaneously oscillating KrF and ArF excimer laser apparatuses has a wide spectral linewidth ranging from 350 to 400 pm. A projection lens made of a material that transmits ultraviolet light, such as KrF and ArF laser light, therefore produces chromatic aberrations in some cases. As a result, the resolution of the projection lens may decrease. To avoid the decrease in the resolution, the spectral linewidth of the laser light output from the gas laser apparatus needs to be narrow enough to make the chromatic aberrations negligible. To this end, a line narrowing module (LNM) including a line narrowing element (such as etalon or grating) is provided in some cases in a laser resonator of the gas laser apparatus to narrow the spectral linewidth. A gas laser apparatus providing a narrowed spectral linewidth is hereinafter referred to as a narrowed-line gas laser apparatus.

### CITATION LIST

### Patent Literature

[PTL 1] U.S. Patent Application Publication No. 2021/0226414
[PTL 2] WO2021/015919
[PTL 3] WO2020/231946

### SUMMARY

A laser apparatus according to an aspect of the present disclosure is a laser apparatus including: a first wavelength variable semiconductor laser configured to output first continuous-wave laser light; a first amplifier configured to pulse and amplify the first laser light and output first pulse laser light; a wavelength conversion system configured to convert a wavelength of the first pulse laser light and output resultant second pulse laser light; an excimer amplifier configured to amplify the second pulse laser light and output resultant third pulse laser light; a monitor module configured to measure a wavelength of the third pulse laser light; and a processor configured to periodically change a target wavelength of the third pulse laser light and control a current for changing the wavelength of the laser light from the first semiconductor laser in such a way that the wavelength of the third pulse laser light becomes the target wavelength based on a measured value of the wavelength of the third pulse laser light output at the same target wavelength.

A method for controlling a wavelength of laser light from a laser apparatus according to another aspect of the present disclosure is a method for controlling a wavelength of laser light from a laser apparatus, the method including: outputting first continuous-wave laser light from a first semiconductor laser; pulsing and amplifying the first laser light and outputting first pulse laser light; converting a wavelength of the first pulse laser light and outputting resultant second pulse laser light; amplifying the second pulse laser light and outputting resultant third pulse laser light; measuring a wavelength of the third pulse laser light; periodically changing a target wavelength of the third pulse laser light; and controlling a current for changing the wavelength of the laser light from the first semiconductor laser in such a way that the wavelength of the third pulse laser light becomes the target wavelength based on a measured value of the wavelength of the third pulse laser light output at the same target wavelength.

A method for manufacturing electronic devices according to another aspect of the present disclosure is a method for manufacturing electronic devices, the method including: generating third pulse laser light by using a laser apparatus; outputting the third pulse laser light to an exposure apparatus; and exposing a photosensitive substrate to the third pulse laser light in the exposure apparatus to manufacture the electronic devices, the laser apparatus including a first wavelength variable semiconductor laser configured to output first continuous-wave laser light, a first amplifier configured to pulse and amplify the first laser light and output first pulse laser light, a wavelength conversion system configured to convert a wavelength of the first pulse laser light and output resultant second pulse laser light, an excimer amplifier configured to amplify the second pulse laser light and output the third pulse laser light, a monitor module configured to measure a wavelength of the third pulse laser light, and a processor configured to periodically change a target wavelength of the third pulse laser light and control a current for changing the wavelength of the laser light from the first semiconductor laser in such a way that the wavelength of the third pulse laser light becomes the target wavelength based on a measured value of the wavelength of the third pulse laser light output at the same target wavelength.

### BRIEF DESCRIPTION OF DRAWINGS

Embodiments of the present disclosure will be described below only by way of example with reference to the accompanying drawings.

FIG. 1 is a graph showing two-wavelength parameters in two-wavelength exposure.

FIG. 2 is a graph showing multi-wavelength parameters in multi-wavelength exposure.

FIG. 3 schematically shows the configuration of an exposure system.

FIG. 4 is a top view showing the configuration of a laser apparatus according to Comparative Example.

FIG. 5 is a side view showing the configuration of the laser apparatus according to Comparative Example.

FIG. 6 shows the configuration of an exposure system according to a first embodiment.

FIG. 7 is a flowchart showing the procedure of processes carried out by a laser control processor in the first embodiment.

FIG. 8 is a timing chart showing the relationship between the number of pulses and the wavelength of excimer laser light output from a laser apparatus in the first embodiment.

FIG. 9 is a timing chart showing the relationship between the number of pulses of the excimer laser light output from the laser apparatus and a current value of a current flowing through a semiconductor laser device in the first embodiment.

FIG. 10 schematically shows an example of the configuration of a first semiconductor laser system.

FIG. 11 is a graph showing the spectrum of pulse laser light output from an SOA.

FIG. 12 is a flowchart showing the procedure of processes carried out by a semiconductor laser control processor when the semiconductor laser control processor controls the temperature of the semiconductor laser device based on a target center wavelength.

FIG. 13 is a graph showing the relationship between a set temperature of the semiconductor laser device when the current value is a reference current value, and the wavelength after excimer amplification.

FIG. 14 is a flowchart showing the procedure of processes carried out by the semiconductor laser control processor when the semiconductor laser control processor controls the temperature of the semiconductor laser device based on an average current value.

FIG. 15 schematically shows an example of the configuration of a wavelength conversion system.

FIG. 16 shows graphs indicating the relationship between the wavelength λ after the wavelength conversion and wavelength conversion efficiency η.

FIG. 17 schematically shows an example of the configuration of a nonlinear crystal temperature adjustment system.

FIG. 18 is a graph showing the relationship between the target center wavelength after the wavelength conversion and a temperature at which the wavelength conversion efficiency is maximized.

FIG. 19 is a flowchart showing the procedure of processes carried out by the laser control processor when the laser control processor controls the wavelength conversion system.

FIG. 20 shows graphs showing the relationship between the wavelength after the excimer amplification and the wavelength conversion efficiency.

FIG. 21 shows graphs showing the relationship between the wavelength after the excimer amplification and the wavelength conversion efficiency.

FIG. 22 shows the configuration of an exposure system according to a second embodiment.

FIG. 23 is a flowchart showing the procedure of processes carried out by a laser control processor in the second embodiment.

FIG. 24 is a flowchart showing the procedure of processes carried out by a semiconductor laser control processor when the semiconductor laser control processor controls the temperature of a semiconductor laser device based on the target center wavelength.

FIG. 25 is a flowchart showing the procedure of processes carried out by the semiconductor laser control processor when the semiconductor laser control processor controls the temperature of the semiconductor laser device based on the average current value.

FIG. 26 is a flowchart showing the procedure of processes carried out by the laser control processor when the laser control processor controls a wavelength conversion system.

FIG. 27 shows graphs showing the relationship between the wavelength λ after the excimer amplification and the wavelength conversion efficiency.

FIG. 28 shows graphs showing the relationship between the wavelength λ after the excimer amplification and the wavelength conversion efficiency.

FIG. 29 is a flowchart showing the procedure of processes carried out by the laser control processor when the laser control processor controls the wavelength conversion system.

FIG. 30 is a flowchart showing the procedure of processes carried out by a laser control processor in the two-wavelength exposure in a third embodiment.

FIG. 31 is a flowchart showing the procedure of processes carried out by the laser control processor in the two-wavelength exposure in the third embodiment.

FIG. 32 is a graph showing the relationship between the wavelength after the excimer amplification and a current value of a current flowing through a semiconductor laser device.

FIG. 33 is a flowchart showing the procedure of processes carried out by the laser control processor in the multi-wavelength exposure in the third embodiment.

FIG. 34 is a flowchart showing the procedure of processes carried out by the laser control processor in the multi-wavelength exposure in the third embodiment.

FIG. 35 schematically shows a variation of the configuration of a solid-state seeder.

FIG. 36 schematically shows an example of the configuration of a semiconductor laser system.

FIG. 37 schematically shows an example of the configuration of a semiconductor laser system.

FIG. 38 schematically shows an example of the configuration of an exposure apparatus.

### DETAILED DESCRIPTION

### Contents

1. Description of terms
2. Comparative Example
2.1 Exposure system
2.1.1 Configuration
2.1.2 Operation
2.2 Laser apparatus according to Comparative Example
2.2.1 Configuration
2.2.2 Operation
3. Problems
4. First Embodiment
4.1 Laser apparatus
4.1.1 Configuration
4.1.2 Operation
4.1.2.1 Operation in normal control
4.1.2.2 Operation in two-wavelength control
4.1.3 Effects and advantages
4.1.4 Others
4.2 Semiconductor laser system
4.2.1 Configuration
4.2.2 Operation
4.2.3 Others
4.3 Control of temperature of semiconductor laser performed by laser control processor
4.3.1 First example of flowchart
4.3.2 Second example of flowchart
4.3.3 Effects and advantages
4.4 Wavelength conversion system
4.4.1 Configuration
4.4.2 Operation
4.5 Nonlinear crystal temperature adjustment system
4.5.1 Configuration
4.5.2 Operation
4.5.3 Others
4.6 Wavelength conversion system
4.6.1 Example of flowchart
4.6.2 Operation
4.6.3 Effects and advantages
5. Second Embodiment
5.1 Configuration
5.2 Flowchart executed by laser control processor
5.3 Control of temperature of semiconductor laser
5.3.1 First example of flowchart
5.3.2 Second example of flowchart
5.3.3 Effects and advantages
5.4 Wavelength conversion system
5.4.1 Example of flowchart
5.4.2 Example of flowchart
6. Third Embodiment
6.1 Operation in two-wavelength exposure
6.1.1 Example of flowchart
6.1.2 Example of flowchart
6.2 Operation in multi-wavelength exposure
6.2.1 Example of flowchart
6.2.2 Example of flowchart
7. Fourth Embodiment
7.1 Configuration
7.2 Operation
7.3 Others
8. Fifth Embodiment
8.1 Configuration
8.2 Operation
8.3 Others
8.4 Effects and advantages
9. Sixth Embodiment
9.1 Configuration
9.2 Operation
9.3 Effects and advantages
10. Method for manufacturing electronic devices
11. Others

Embodiments of the present disclosure will be described below in detail with reference to the drawings. The embodiments described below show some examples of the present disclosure and are not intended to limit the contents of the present disclosure. Furthermore, all configurations and operations described in the embodiments are not necessarily essential as configurations and operations in the present disclosure. The same elements have the same reference characters, and no redundant description of the same elements will be made.

### 1. Description of Terms

In the present specification, “two-wavelength exposure” refers to causing a laser apparatus to undergo laser oscillation alternately at wavelengths λ_{S} and λ_{L} on a pulse basis to perform the two-wavelength exposure.

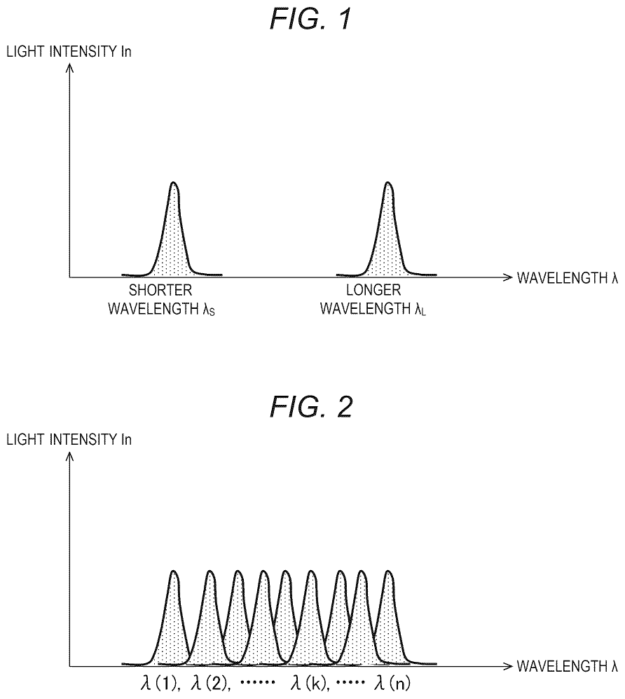

FIG. 1 is a graph showing two-wavelength parameters in two-wavelength exposure. In FIG. 1, the horizontal axis represents a wavelength λ, and the vertical axis represents a light intensity In. In the two-wavelength exposure, the shorter wavelength is called λ_{S}, and the longer wavelength is called λ_{L}, as shown in FIG. 1. A center wavelength λc of a two-wavelength spectrum is expressed by λc=(λ_{L}+λ_{S})/2.

In the present specification, “multi-wavelength exposure” refers to causing a laser apparatus to undergo laser oscillation at wavelengths λ(1), λ(2), λ(3), . . . , and λ(n) in this order on a pulse basis to periodically change the oscillation wavelength to perform the multi-wavelength exposure.

FIG. 2 is a graph showing multi-wavelength parameters in multi-wavelength exposure. In FIG. 2, the horizontal axis represents the wavelength λ, and the vertical axis represents the light intensity In. The wavelengths in the multi-wavelength exposure are called a wavelength λ(1), a wavelength λ(2), . . . , a wavelength λ(k), . . . , and a wavelength λ(n) in ascending order, as shown in FIG. 2. The center wavelength λc of a multi-wavelength spectrum is expressed by λc={λ(1)+λ(2)+λ(3)+ . . . +λ(n)}/n.

### 2. Comparative Example

### 2.1 Overview of Exposure System

### 2.1.1 Configuration

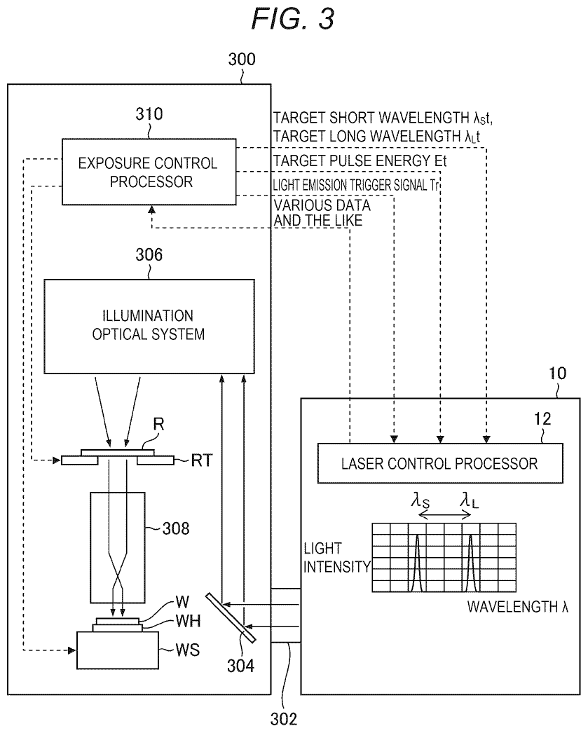

FIG. 3 schematically shows the configuration of an exposure system. The exposure system includes a laser apparatus 10 and an exposure apparatus 300. The laser apparatus 10 includes a laser control processor 12. The processor in the present specification is a processing apparatus including a storage that stores a control program and a CPU (central processing unit) that executes the control program. The processor is particularly configured or programmed to carry out a variety of processes described in the present disclosure.

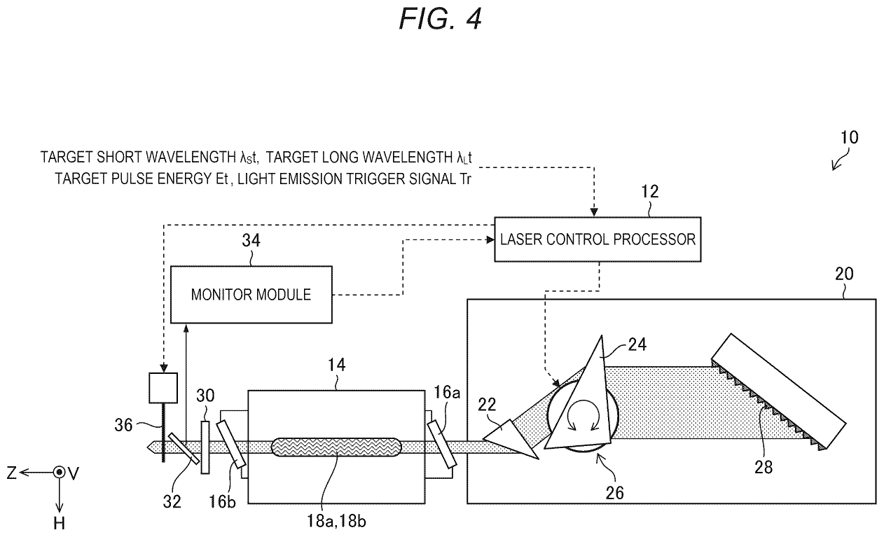

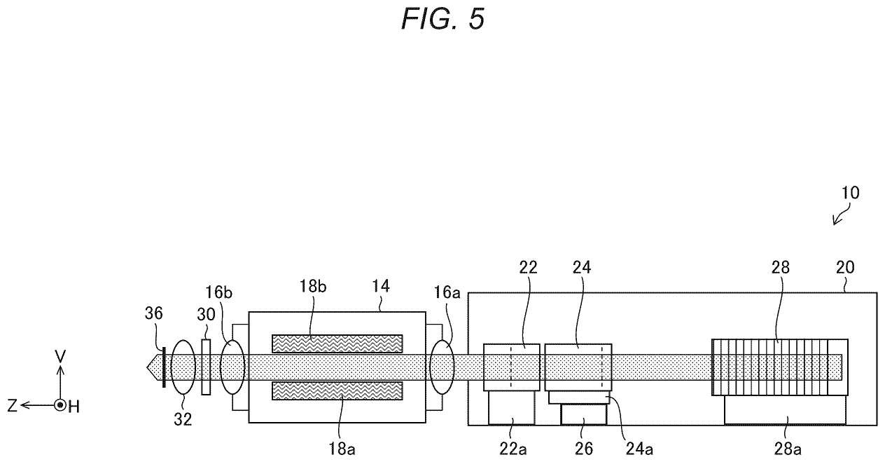

The laser apparatus 10 is configured to output pulse laser light having a changeable oscillation wavelength toward the exposure apparatus 300. The configuration of the laser apparatus 10 will be described later (FIGS. 4 and 5).

The exposure apparatus 300 includes a beam delivery unit (BDU) 302, a highly reflective mirror 304, an illumination optical system 306, a reticle stage RT, a projection optical system 308, a wafer stage WS, and an exposure control processor 310. The wafer stage WS is provided with a wafer holder WH, and a wafer W is placed on the wafer holder WH.

The BDU 302 is an optical system that delivers the pulse laser light from the laser apparatus 10 to the exposure apparatus 300. The highly reflective mirror 304 is so disposed that the pulse laser light having passed through the BDU 302 enters the illumination optical system 306.

The illumination optical system 306 is an optical system that shapes the beam of the pulse laser light incident from the laser apparatus 10 and guides the shaped pulse laser light to a reticle R placed on the reticle stage RT. The illumination optical system 306 shapes the beam of the pulse laser light in such a way that the pulse laser light has an approximately rectangular beam cross-sectional shape and has an approximately uniform light intensity distribution, and illuminates a reticle pattern of the reticle R with the shaped pulse laser light. The projection optical system 308 performs reduction projection on the pulse laser light having passed through the reticle R to bring the pulse laser light into focus on the wafer W on the wafer holder WH. The wafer W is a photosensitive substrate, such as a semiconductor wafer coated with a photoresist film.

The exposure control processor 310 is a processing apparatus including a storage that stores a control program, and a CPU that executes the control program. The exposure control processor 310 oversees control of the exposure apparatus 300. The exposure control processor 310 is connected to the reticle stage RT and the wafer stage WS. The exposure control processor 310 is further connected to the laser control processor 12.

### 2.1.2 Operation

The exposure control processor 310 transmits a variety of parameters including a target short wavelength Δ_{S}t, a target long wavelength λ_{L}t, and target pulse energy Et, and a light emission trigger signal Tr to the laser control processor 12. The laser control processor 12 controls the laser apparatus 10 in accordance with the parameters and the signal. That is, the laser control processor 12 controls the oscillation wavelength by periodically changing the target wavelength in such a way that the wavelength λ of the pulse laser light output from the laser apparatus 10 becomes the target short wavelength Δ_{S}t or the target long wavelength Δ_{L}t, controls excitation intensity in such a way that pulse energy E becomes the target pulse energy Et, and causes the laser apparatus 10 to output the pulse laser light in accordance with the light emission trigger signal Tr.

The laser apparatus 10 thus performs the two-wavelength oscillation at the target short wavelength λ_{S}t and the target long wavelength λ_{L}t at the target pulse energy Et, and outputs the pulse laser light in accordance with the light emission trigger signal Tr.

Furthermore, the laser control processor 12 transmits a variety of data and other pieces of information to the exposure control processor 310. The variety of data include measured data such as the wavelength and pulse energy of the pulse laser light output in accordance with the light emission trigger signal Tr.

The exposure control processor 310 synchronously moves the reticle stage RT and the wafer holder WH on the wafer stage WS in parallel in directions opposite to each other. The wafer W is thus exposed to the pulse laser light having reflected the reticle pattern.

To form a 3D NAND pattern or a contact hole pattern, the exposure is so performed that the waveform of an integrated spectrum is that of a desired two-wavelength spectrum to ensure the depth of focus.

### 2.2 Laser Apparatus According to Comparative Example

### 2.2.1 Configuration

FIGS. 4 and 5 are a top view and a side view showing the configuration of the laser apparatus 10 according to Comparative Example. Comparative Example in the present disclosure is an aspect that the applicant is aware of as known only by the applicant, and is not a publicly known example that the applicant is self-aware of.

The laser apparatus 10 shown in FIGS. 4 and 5 is a single-wavelength oscillation, narrowed-line excimer laser apparatus, and includes the laser control processor 12, a chamber 14, an LNM 20, an output coupling mirror 30, a beam splitter 32, a monitor module 34, and a light-exiting-port shutter 36.

The LNM 20 includes a first prism 22, a second prism 24, a rotary stage 26, and a grating 28. The first prism 22, the second prism 24, and the grating 28 are supported by holders 22a, 24a, and 28a, respectively. The first prism 22 and the second prism 24 are disposed so as to function as a beam expander. The grating 28 is disposed in the Littrow arrangement, which causes the angle of incidence of the light beam incident from the second prism 24 on the grating 28 to be equal to the angle of diffraction of the diffracted light having a desired wavelength.

The second prism 24 is disposed on the rotary stage 26 via the holder 24a. The rotary stage 26 is a stage being rotatable by a piezoelectric device that is not shown and being quickly responsive to some extent. The second prism 24 is disposed so as to change the angle of incidence of the light to be incident on the grating 28 when the rotary stage 26 rotates the second prism 24 around a V-axis.

The output coupling mirror 30 and the LNM 20 are arranged to constitute an optical resonator. The chamber 14 is disposed in the optical path of the optical resonator.

The chamber 14 includes windows 16a and 16b and a pair of electrodes 18a and 18b. A laser gas is supplied into the chamber 14 from a gas supply apparatus that is not shown. The laser gas may be an excimer laser gas containing, for example, an Ar or Kr gas as a rare gas, an F₂ gas as a halogen gas, and an Ne gas as a buffer gas.

The electrodes 18a and 18b are so disposed in the chamber 14 that the electrodes face each other in the V direction, and that the longitudinal direction of the electrodes 18a and 18b coincides with the optical path of the optical resonator. The laser apparatus 10 further includes a pulse power module (PPM) and a charger neither of which is shown. The PPM includes a switch and a charging capacitor and is connected to the electrode 18b via feedthroughs in an electrically insulating member that is not shown. The electrode 18a is connected to the chamber 14, which is grounded. The charger charges the charging capacitor of the PPM in accordance with an instruction from the laser control processor 12.

The windows 16a and 16b are so disposed that the pulse laser light having been excited and amplified by the discharge between the electrodes 18a and 18b passes through the windows.

The output coupling mirror 30 is coated with a film that reflects part of the pulse laser light and transmits another part thereof. The beam splitter 32 is disposed in the optical path of the pulse laser light output via the output coupling mirror 30. The beam splitter 32 is so disposed that light reflected off the beam splitter 32 enters the monitor module 34. Note that the beam splitter 32 may be incorporated in the monitor module 34.

The monitor module 34 includes a pulse energy measuring device and a spectrum monitor. The pulse energy measuring device includes a photosensor that is not shown. The photosensor may be a photodiode that is resistant to ultraviolet light and has an excellent high-speed response. The spectrum monitor may detect wavelengths, for example, with an etalon spectrometer.

The light-exiting-port shutter 36 is disposed in the optical path of the pulse laser light output from the laser apparatus 10 to the exterior thereof and can block and unblock the pulse laser light toward the exterior. The pulse laser light having passed through the beam splitter 32 exits out of the laser apparatus 10 via the light-exiting-port shutter 36.

### 2.2.2 Operation

The laser control processor 12 acquires the variety of parameters including the target short wavelength λ_{S}t, the target long wavelength λ_{L}t, and the target pulse energy Et. The laser control processor 12 further receives the light emission trigger signal Tr.

The laser control processor 12 controls a voltage to be applied to the electrode 18b based on the received target pulse energy Et. The control of the voltage includes feedback control based on the pulse energy measured by the monitor module 34.

A pulse-shaped high voltage is applied to the electrode 18b under the control performed by the laser control processor 12. When the high voltage is applied to the electrode 18b, discharge occurs in a discharge space between the electrodes 18a and 18b. The energy of the discharge excites the laser gas in the chamber 14, and the state of the excited laser gas transitions to a high energy level. Thereafter, when the excited laser gas transitions to a low energy level, the laser gas emits light having a wavelength according to the difference between the energy levels.

The light generated in the chamber 14 exits as a light beam out of the chamber 14 via the windows 16a and 16b. The beam width of the light beam having exited via the window 16a is enlarged by the first prism 22 and the second prism 24 in a plane parallel to an HZ plane, which is a plane perpendicular to the V-axis. The light beam having passed through the first prism 22 and the second prism 24 is incident on the grating 28.

The light beam incident on the grating 28 is reflected off and diffracted by multiple grooves of the grating 28 in the direction according to the wavelength of the light.

The first prism 22 and the second prism 24 reduce the beam width of the light beam having returned from the grating 28 in the plane parallel to the HZ plane, and cause the resultant light beam to return into the chamber 14 via the window 16a.

The output coupling mirror 30 transmits part of the light beam having exited via the window 16b and reflects another part of the light beam back into the chamber 14.

The light beam having exited out of the chamber 14 thus travels back and forth between the LNM 20 and the output coupling mirror 30. The light beam is amplified whenever passing through the discharge space in the chamber 14. The light beam undergoes the line narrowing operation whenever deflected back by the LNM 20. The light beam thus having undergone the laser oscillation and the line narrowing operation is output as the pulse laser light via the output coupling mirror 30.

The monitor module 34 measures the pulse energy and the wavelength of the pulse laser light reflected off the beam splitter 32, and transmits the measured pulse energy and wavelength to the laser control processor 12.

The pulse laser light having passed through the beam splitter 32 is output from the laser apparatus 10 via the light-exiting-port shutter 36.

The laser control processor 12 controls the voltage to be applied to the electrode 18b based on the received target pulse energy Et. The control of the voltage includes feedback control based on the pulse energy measured by the monitor module 34.

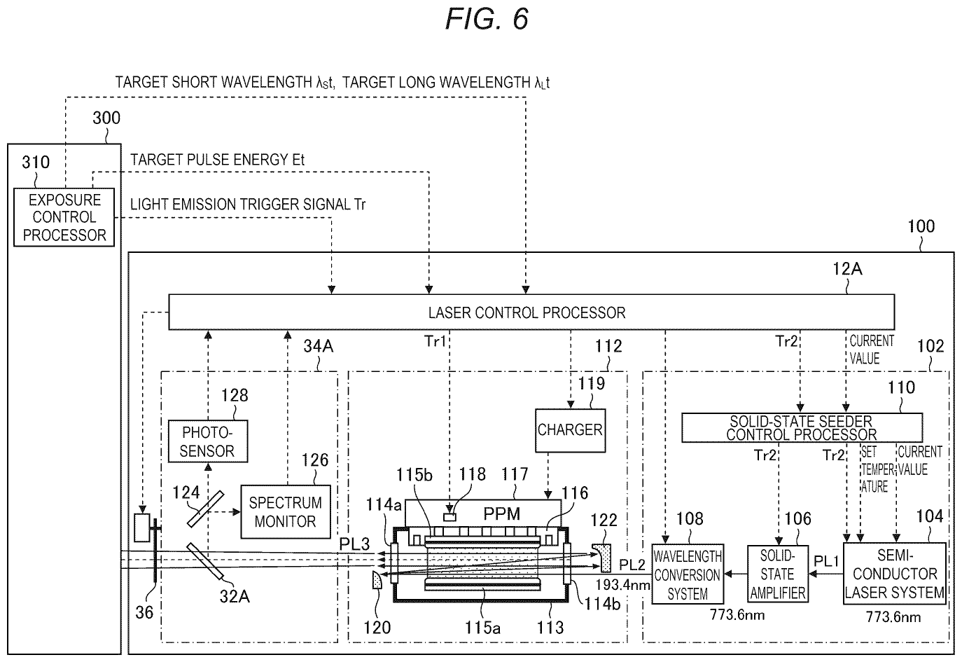

The laser control processor 12 changes the oscillation wavelength by causing the rotary stage 26, at which the second prism 24 is disposed, to control the angle of incidence of the light to be incident on the grating 28. The laser control processor 12 measures the wavelength of the pulse laser light with a spectrum monitor 126 (see FIG. 6) in the monitor module 34, and controls the rotary stage 26 in such a way that the oscillation wavelength alternately changes to two target wavelengths (As and λ_{L}) on a pulse basis. Performing the control described above controls the oscillation wavelength of the pulse laser light output from the laser apparatus 10 to the target short wavelength λ_{S}t and the target long wavelength λ_{L}t on a pulse basis.

### 3. Problems

To generate a two-wavelength exposure spectral waveform, it has been necessary to change the wavelength with high precision on a pulse basis. Furthermore, when the second prism 24 or any other optical element of the LNM 20 is rotated by the rotary stage 26 on a pulse basis, it has been difficult, as the repetition frequency (4 kHz or higher) of the laser apparatus 10 increases, to stabilize the wavelength of the output pulse laser light at each of the two target wavelengths (Ast and λ_{L}t) with high precision.

### 4. First Embodiment

A first embodiment shows a case where a laser apparatus includes a solid-state seeder and an excimer amplifier, and the spectrum of the pulse laser light output from the laser apparatus is a two-wavelength spectrum formed by the target shortest wavelength λ_{S}t and the target longest wavelength λ_{L}t.

### 4.1 Laser Apparatus

### 4.1.1 Configuration

FIG. 6 shows the configuration of an exposure system according to a first embodiment. The exposure system includes a laser apparatus 100 and an exposure apparatus 300.

The laser apparatus 100 includes a laser control processor 12A, a monitor module 34A, a solid-state seeder 102 as a master oscillator (MO), and an excimer amplifier 112 as a power amplifier (PA).

The solid-state seeder 102 includes a semiconductor laser system 104 which outputs pulse laser light, a solid-state amplifier 106 which amplifies the pulse laser light, a wavelength conversion system 108, and a solid-state seeder control processor 110.

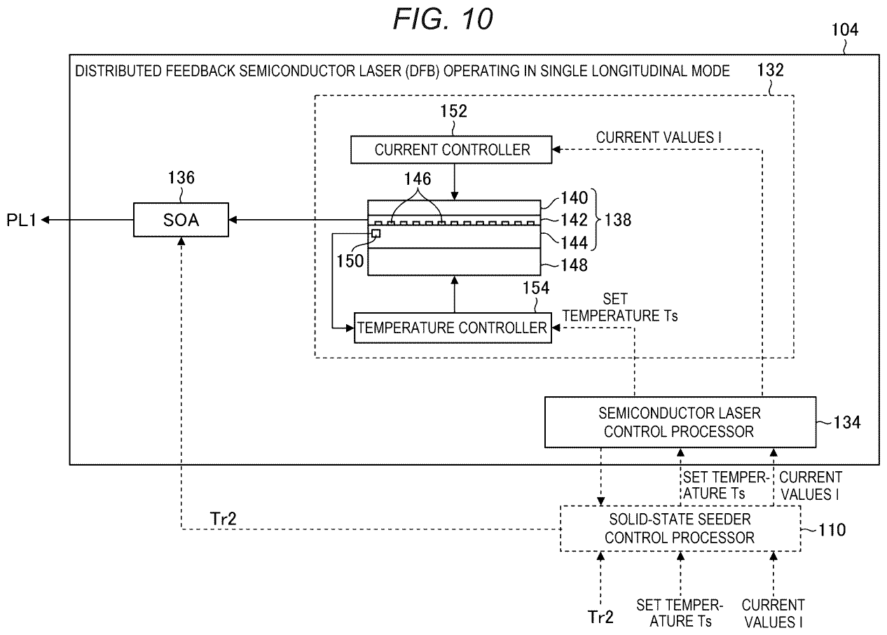

The semiconductor laser system 104 includes a distributed feedback semiconductor laser 132 (see FIG. 10) which outputs a continuous wave (CW) laser light having a wavelength of about 773.6 nm, and a semiconductor optical amplifier (SOA) 136 (see FIG. 10). The semiconductor laser 132 is configured to have a variable oscillation wavelength by controlling the temperature of a semiconductor laser device 138 (see FIG. 10) and/or the value of a current flowing through the semiconductor laser device 138.

The SOA 136 pulses and amplifies the CW laser light output from the semiconductor laser 132. The SOA 136, through which a pulse current is caused to flow, pulses and amplifies the CW laser light and outputs pulse laser light PL1 having undergone the pulsing and amplification. The SOA 136 in the first embodiment is an example of the “first amplifier” in the present disclosure.

The solid-state amplifier 106 includes a titanium-sapphire crystal and a pumping pulse laser neither of which is shown. The titanium sapphire crystal is disposed in the optical path of the pulse laser light having undergone the pulsing and amplification performed by the SOA 136. The pumping pulse laser is a laser apparatus that outputs second harmonic of the laser light from a YLF laser. YLF (yttrium lithium fluoride) is a solid-state laser crystal expressed by a chemical formula LiYF₄.

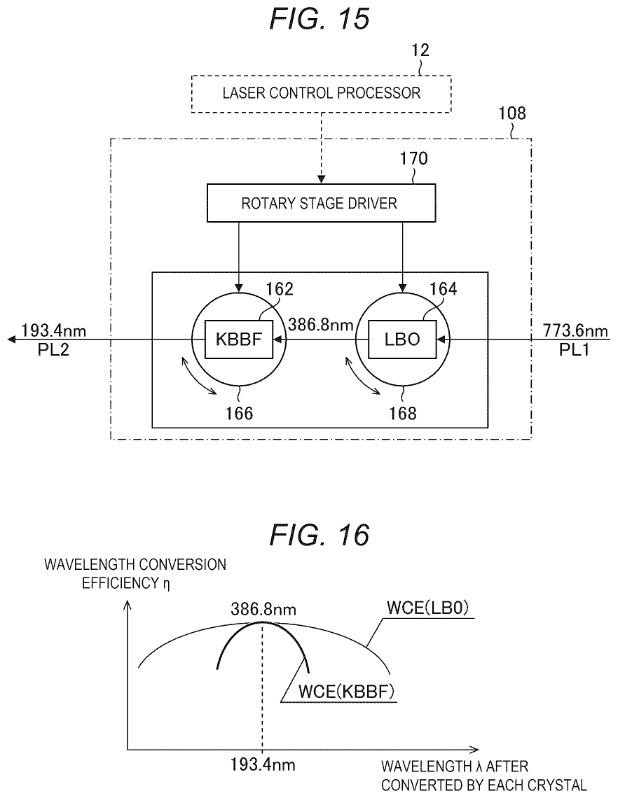

The wavelength conversion system 108 is a wavelength conversion system that includes a nonlinear crystal and converts the wavelength of pulse laser light incident thereon to output resultant fourth harmonic light. The configuration of the wavelength conversion system 108 will be described later (see FIG. 15).

The solid-state seeder control processor 110 controls the semiconductor laser system 104 and the solid-state amplifier 106 based on inputs from the laser control processor 12A.

The excimer amplifier 112 includes a chamber 113, a pulse power module (PPM) 117, a charger 119, a convex mirror 120, and a concave mirror 122. The chamber 113 contains an ArF laser gas, windows 114a and 114b, a pair of electrodes 115a and 115b, and an electrically insulating member 116.

The PPM 117 includes a switch 118 and a charging capacitor that is not shown. The PPM 117 is connected to the electrode 115b via feedthroughs in the electrically insulating member 116 in the chamber 113.

The charger 119 retains electrical energy to be supplied to the PPM 117. The charger 119 is connected to the charging capacitor, which is not shown. The electrode 115a is connected to ground potential.

The convex mirror 120 and the concave mirror 122 are so disposed that pulse laser light PL2 output from the wavelength conversion system 108 passes through the discharge space between the electrodes 115a and 115b three times for beam expansion.

The monitor module 34A includes beam splitters 32A and 124, the spectrum monitor 126, and a photosensor 128. The beam splitter 32A is so disposed in the optical path of pulse laser light PL3 output from the excimer amplifier 112 that the pulse laser light reflected off the beam splitter 32A is incident on the beam splitter 124. The beam splitter 32A may be disposed outside the monitor module 34A, as the beam splitter 32 shown in FIG. 4.

The beam splitter 124 is so disposed that the pulse laser light PL3 reflected off the beam splitter 124 enters the spectrum monitor 126, and that the pulse laser light PL3 having passed through the beam splitter 124 enters the photosensor 128.

The spectrum monitor 126 monitors the spectrum of the pulse laser light incident thereon and detects the oscillation wavelength of the incident pulse laser light. The spectrum monitor 126 may, for example, be an etalon spectrometer. An etalon spectrometer includes a diffuser plate that diffuses sample light, an etalon, a light collection lens disposed on the light exiting side of the etalon, and a photodiode array disposed at the focal plane of the light collection lens to detect the pattern of interference fringes, and can detect the wavelength of the pulse laser light by measuring the diameters of the interference fringes. The photosensor 128 detects the pulse energy of the pulse laser light incident thereon. The photosensor 128 may, for example, be a photodiode.

### 4.1.2 Operation

### 4.1.2.1 Operation in Normal Control

The semiconductor laser device 138 outputs continuous-wave first laser light having the wavelength of about 773.6 nm. Thereafter, when the pulse current is caused to flow through the SOA 136 at the timing when a trigger signal Tr2 is input, pulsing and amplification is performed, so that the pulse laser light PL1 is output. The pulse laser light PL1 in the first embodiment is an example of the “first pulse laser light” in the present disclosure.

The pulse laser light is further amplified by the solid-state amplifier 106.

The wavelength conversion system 108 converts the pulse laser light amplified by the solid-state amplifier 106 into fourth harmonic light having a wavelength of about 193.4 nm, and outputs the pulse laser light PL2. The pulse laser light PL2 in the first embodiment is an example of the “second pulse laser light” in the present disclosure. The fourth harmonic light in the first embodiment is an example of the “first harmonic light” in the present disclosure.

The range over which the wavelength of the pulse laser light PL2 output from the solid-state seeder 102 is variable is from about 193.2 nm to 193.5 nm, which is the wavelength band over which the excimer amplifier 112 performs the amplification.

A trigger signal Tr1 is input to the switch 118 of the PPM 117, and the trigger signal Tr2 is input to the SOA 136 and the pumping pulse laser so that discharge occurs in synchronization with the timing when the pulse laser light PL2 output from the solid-state seeder 102 enters the discharge space in the chamber 113 of the excimer amplifier 112.

As a result, the pulse laser light PL2 output from the solid-state seeder 102 undergoes three-pass amplification performed by the excimer amplifier 112. The excimer amplifier 112 outputs the pulse laser light PL3. The pulse laser light PL3 in the first embodiment is an example of the “third pulse laser light” in the present disclosure.

The pulse laser light PL3 is sampled by the beam splitter 32A of the monitor module 34A, which then measures the pulse energy E and the wavelength λ.

The laser control processor 12A and the solid-state seeder control processor 110 control the oscillation wavelength at which the semiconductor laser device 138 of the semiconductor laser system 104 performs laser oscillation in such a way that the wavelength λ of the pulse laser light PL3 output from the excimer amplifier 112 and measured by the monitor module 34A approaches a target value.

The laser control processor 12A and the solid-state seeder control processor 110 control a charging voltage of the charger 119 in such a way that the pulse energy E of the pulse laser light PL3 output from the excimer amplifier 112 and measured by the monitor module 34A approaches a target value.

### 4.1.2.2 Operation in Two-Wavelength Control

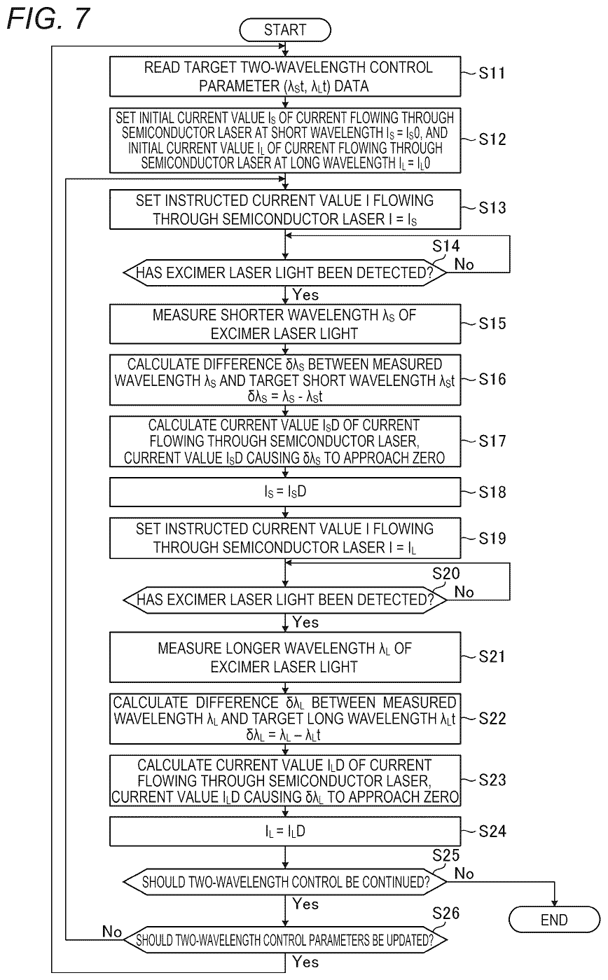

FIG. 7 is a flowchart showing the procedure of processes carried out by the laser control processor 12A in the first embodiment. The procedure of the processes carried out by the laser control processor 12A in the first embodiment is an example of the “method for controlling the wavelength of laser light from a laser apparatus” in the present disclosure.

In step S11, the laser control processor 12A reads target two-wavelength control parameter data from the exposure control processor 310. The target two-wavelength control parameter data include the target short wavelength λ_{S}t and the target long wavelength λ_{L}t.

In step S12, the laser control processor 12A sets a current value I_{S}, which is the value of the current caused to flow through the semiconductor laser 132 when the target wavelength is the short wavelength, and a current value I_{L}, which is the value of the current caused to flow through the semiconductor laser 132 when the target wavelength is the long wavelength, at initial values I_{S}0 and I_{L}0, respectively. That is, the laser control processor 12A sets the initial values as follows: I_{S}=I_{S}0; and I_{L}=I_{L}0.

In step S13, the laser control processor 12A sets an instructed current value I of the current flowing through the semiconductor laser 132 at Is. That is, the laser control processor 12A sets the current value as follows: I=I_{S}.

In step S14, the laser control processor 12A evaluates whether the excimer laser light has been detected by the spectrum monitor 126. When the excimer laser light has not been detected (No in step S14), the laser control processor 12A waits until the excimer laser light is detected. When the excimer laser light has been detected (Yes in step S14), the laser control processor 12A proceeds to the process in step S15.

In step S15, the laser control processor 12A causes the spectrum monitor 126 to measure the shorter wavelength λ_{S} of the excimer laser light.

In step S16, the laser control processor 12A calculates a difference δλ_{S} between the wavelength λ_{S} measured in step S15 and the target short wavelength λ_{S}t. That is, the laser control processor 12A calculates the difference δλ_{S} as follows: δλ_{S}=λ_{S}−λ_{S}t

In step S17, the laser control processor 12A calculates a current value I_{S}D of the current flowing through the semiconductor laser 132, the current value I_{S}D causing the difference δλ_{S} calculated in step S16 to approach zero.

In step S18, the laser control processor 12A sets the current value I_{S}, which is the value of the current caused to flow through the semiconductor laser 132 when the target wavelength is the short wavelength, at the current values I_{S}D calculated in step S17. That is, the laser control processor 12A sets the current value I_{S} as follows: I_{S}=I_{S}D.

The processes in steps S13 to S18 are therefore wavelength measurement and control at the short wavelength.

In step S19, the laser control processor 12A sets the instructed current value I of the current flowing through the semiconductor laser 132 at I_{L}. That is, the laser control processor 12A sets the current value I as follows: I=I_{L}.

In step S20, the laser control processor 12A evaluates whether the excimer laser light has been detected by the spectrum monitor 126. When the excimer laser light has not been detected (No in step S20), the laser control processor 12A waits until the excimer laser light is detected. When the excimer laser light has been detected (Yes in step S20), the laser control processor 12A proceeds to the process in step S21.

In step S21, the laser control processor 12A causes the spectrum monitor 126 to measure the longer wavelength λ_{L} of the excimer laser light.

In step S22, the laser control processor 12A calculates a difference δλ_{L} between the wavelength λ_{L} measured in step S21 and the target long wavelength λ_{L}t. That is, the laser control processor 12A calculates the difference SAL as follows: δλ_{L}=λ_{L}−λ_{L}t.

In step S23, the laser control processor 12A calculates a value I_{L}D of the current flowing through the semiconductor laser 132, the current value I_{L}D causing the difference δλ_{L} calculated in step S22 to approach zero.

In step S24, the laser control processor 12A sets the current value I_{L}, which is the value of the current caused to flow through the semiconductor laser 132 when the target wavelength is the long wavelength, at the current values I_{L}D calculated in step S23. That is, the laser control processor 12A sets the current value I_{L} as follows: I_{L}=I_{L}D.

The processes in steps S19 to S24 are therefore wavelength measurement and control at the long wavelength.

In step S25, the laser control processor 12A evaluates whether the two-wavelength control should be continued. When the two-wavelength control should be continued (Yes in step S25), the laser control processor 12A proceeds to the process in step S26. When the two-wavelength control should not be continued (No in step S25), the laser control processor 12A terminates the processes in the flowchart.

In step S26, the laser control processor 12A evaluates whether the two-wavelength control parameters should be updated. When the two-wavelength control parameters should not be updated (No in step S26), the laser control processor 12A returns to the process in step S13. When the two-wavelength control parameters should be updated (Yes in step S26), the laser control processor 12A returns to the process in step S11.

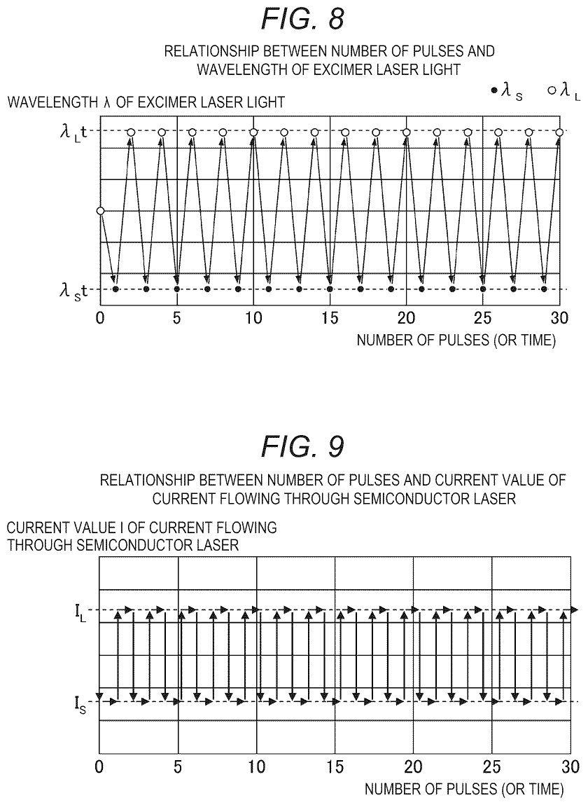

FIG. 8 is a timing chart showing the relationship between the number of pulses and the wavelength of the excimer laser light output from the laser apparatus 100 in the first embodiment. In FIG. 8, the horizontal axis represents the number of pulses (or time), and the vertical axis represents the wavelength. The laser apparatus 100 alternately outputs the excimer laser light having the wavelength λ_{S}t and the excimer laser light having the wavelength λ_{L}t on a pulse basis, as shown in FIG. 8. In the description, the excimer laser light having the wavelength λ_{S}t is output at odd-numbered pulses, and the excimer laser light having the wavelength λ_{L}t is output at even-numbered pulses.

FIG. 9 is a timing chart showing the relationship between the number of pulses of the excimer laser light output from the laser apparatus 100 and the current value of the current flowing through the semiconductor laser 132 in the first embodiment. In FIG. 9, the horizontal axis represents the number of pulses (or time), and the vertical axis represents the current value. The laser apparatus 100 alternately changes the current value of the current flowing through the semiconductor laser 132 to the current value I_{S} at the short wavelength and the current value I_{L} at the long wavelength, as shown in FIG. 9. At the odd-numbered pulses, the current value is controlled to be the current value I_{S} at the short wavelength, and at the even-numbered pulses, the current value is controlled to be the current value I_{L} at the long wavelength.

When the target wavelength is periodically changed from the target short wavelength λ_{S}t to the target long wavelength λ_{L}t and vice versa, the wavelength control performed is performed as will be described below.

The laser apparatus 100 measures the shorter wavelength λ_{S} of the two-wavelength spectrum, and feeds the result of the measurement back to the current value I_{S}, which is the value of the current flowing through the semiconductor laser 132 that outputs laser light having the shorter wavelength. That is, when outputting the laser light having the target short wavelength λ_{S}t, the laser control processor 12A controls the current value I_{S} of the current flowing through the semiconductor laser 132 based on the measured value of the most recent wavelength λ_{S} of the laser light output at the same target short wavelength λ_{S}t.

The laser apparatus 100 further measures the longer wavelength λ_{L} of the two-wavelength spectrum, and feeds the result of the measurement back to the current value I_{L}, which is the value of the current flowing through the semiconductor laser 132 that outputs laser light having the longer wavelength. That is, when outputting the laser light having the target long wavelength λ_{L}t, the laser control processor 12A controls the current value I_{L} of the current flowing through the semiconductor laser 132 based on the measured value of the most recent wavelength λ_{L} of the laser light output at the same target long wavelength λ_{L}t.

### 4.1.3 Effects and Advantages

The laser apparatus 100, which includes the solid-state seeder 102 including the semiconductor laser 132 and the excimer amplifier 112, controls the current value of the current caused to flow through the semiconductor laser 132 in such a way that the wavelength λ measured on a pulse basis alternately approaches the target short wavelength λ_{S}t and the target long wavelength λ_{L}t. The thus configured laser apparatus 100 can perform highly accurate two-wavelength exposure even at a repetition frequency of 4 kHz or higher.

### 4.1.4 Others

In the first embodiment, the CW light from the semiconductor laser 132 is converted into pulse laser light by causing a pulse current to pass through the SOA 136, but the pulse laser light is not necessarily generated as described above. For example, the CW light from the semiconductor laser 132 may be amplified into pulse laser light by exciting the titanium sapphire crystal of the solid-state amplifier 106 with pulse excitation light.

The solid-state seeder 102 may include a system that includes a CW-oscillation semiconductor laser device and a pulsing apparatus, and controls the current value of the current caused to flow through the semiconductor laser device to change the wavelength. The solid-state seeder 102 may instead include a system using an optical shutter in place of the SOA 136 to perform the light pulsing. The optical shutter may, for example, be the combination of an electro-optical (EO) Pockels cell and polarizers.

The first embodiment shows a three-multipath amplifier as the amplifier, but a multipath amplifier is not necessarily used, and the amplifier may, for example, be an amplifier with an optical resonator such as a Fabry-Perot resonator or a ring resonator.

The first embodiment has been described with reference to the case where a solid-state seeder and an ArF excimer amplifier are employed, but not necessarily, and the combination of an excimer amplifier containing a KrF laser gas and a solid-state seeder that performs oscillation in a wavelength band over which the KrF excimer is amplified may be employed. As a specific example, the solid-state seeder may be a semiconductor laser system that outputs pulse laser light having a wavelength of about 745.2 nm, a solid-state amplifier, and a wavelength conversion system that converts the pulse laser light in terms of wavelength into third harmonic light having a wavelength of about 248.4 nm. Wavelength converters in this case may be an LBO crystal that converts the pulse laser light in terms of wavelength into second harmonic light, and a CLBO crystal that performs sum frequency operation on the second harmonic light and the fundamental-wave light.

### 4.2 Example of Semiconductor Laser System

### 4.2.1 Configuration

FIG. 10 schematically shows an example of the configuration of the semiconductor laser system 104.

The semiconductor laser system 104 includes the distributed feedback (DFB) semiconductor laser 132 operating in the single longitudinal mode, a semiconductor laser control processor 134, and the SOA 136. The semiconductor laser 132 includes the semiconductor laser device 138, a Peltier device 148, a temperature sensor 150, a current controller 152, and a temperature controller 154. The semiconductor laser device 138 includes a first cladding layer 140, an active layer 142, and a second cladding layer 144 and further includes a grating 146 at the boundary between the active layer 142 and the second cladding layer 144. The semiconductor laser 132 in the first embodiment is an example of the “first semiconductor laser” in the present disclosure.

### 4.2.2 Operation

The oscillation center wavelength at which the semiconductor laser 132 operates can be changed by changing a set temperature Ts of the semiconductor laser device 138 and/or the current value I of the current flowing through the semiconductor laser device 138. The solid-state seeder control processor 110 acquires the set temperature Ts and the current value I from the laser control processor 12A, and transmits the acquired parameters to the semiconductor laser control processor 134. The semiconductor laser control processor 134 controls the temperature controller 154 and the current controller 152 in accordance with the set temperature Ts and the current value I, respectively.

To change the oscillation wavelength, at which the semiconductor laser 132 perform laser oscillation at high speed, the current value I of the current flowing through the semiconductor laser 132 is changed at high speed. The wavelength of the CW laser light can thus be changed at high speed.

The solid-state seeder control processor 110 acquires the trigger signal Tr2 from the laser control processor 12A. When the trigger signal Tr2 is input to the solid-state seeder 102, a pulse signal is input to the SOA 136.

Causing a pulse current according to the pulse signal to pass through the SOA 136 pulses and amplifies the CW laser light output from the semiconductor laser 132, so that pulse laser light is output.

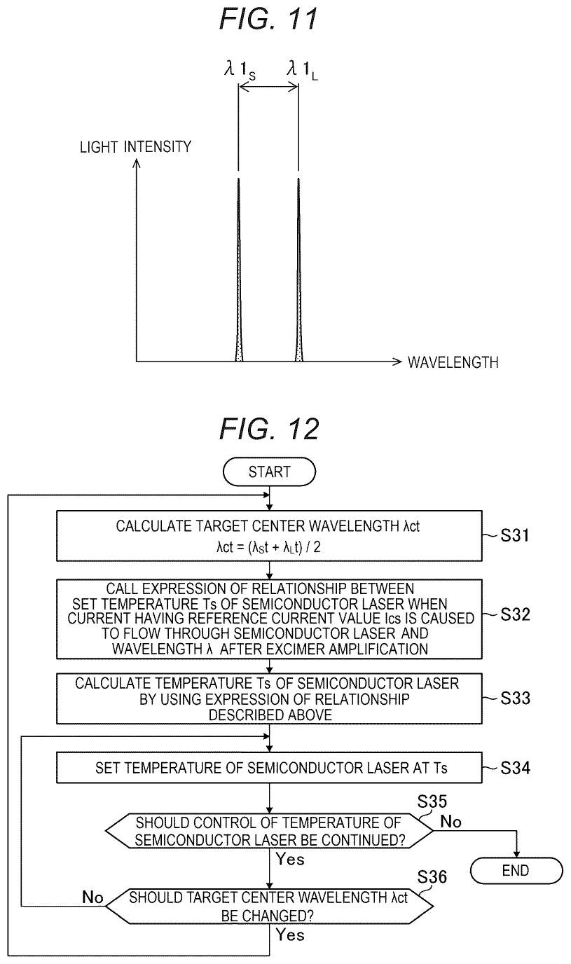

FIG. 11 is a graph showing the spectrum of the pulse laser light output from the SOA 136. The SOA 136 outputs pulse laser light having two wavelengths, pulse laser light having a wavelength of Als and pulse laser light having a wavelength of λLL, as shown in FIG. 11.

### 4.2.3 Others

The SOA 136 may receive a DC current flowing therethrough to amplify the CW laser light. In this case, the downstream solid-state amplifier 106 is an amplifier that pulses and amplifies the CW laser light.

### 4.3 Control of Temperature of Semiconductor Laser Performed by Laser Control Processor

### 4.3.1 First Example of Flowchart

FIG. 12 is a flowchart showing the procedure of processes carried out by the semiconductor laser control processor 134 when the semiconductor laser control processor 134 controls the temperature of the semiconductor laser 132 based on a target center wavelength λct.

In step S31, the laser control processor 12A calculates the target center wavelength λct, which is the average of the target wavelengths. That is, the laser control processor 12A calculates the target center wavelength λct as follows: λct=(λ_{S}t+λ_{L}t)/2.

In step S32, the laser control processor 12A calls the expression of the relationship between the set temperature Ts of the semiconductor laser 132 when a current having a reference current value Ics is caused to pass through the semiconductor laser 132, and the wavelength λ after the excimer amplification.

In step S33, the laser control processor 12A calculates the set temperature Ts of the semiconductor laser 132 at the target center wavelength λct, by using the expression of the relationship called in step S32.

In step S34, the laser control processor 12A sets the temperature of the semiconductor laser 132 to the set temperature Ts calculated in step S33.

In step S35, the laser control processor 12A evaluates whether the control of the temperature of the semiconductor laser 132 should be continued. When the temperature control should not be continued (No in step S35), the laser control processor 12A terminates the processes in the flowchart. When the temperature control should be continued (Yes in step S35), the laser control processor 12A proceeds to the process in step S36.

In step S36, the laser control processor 12A evaluates whether the target center wavelength λct of the laser light from the semiconductor laser 132 should be changed. When the target center wavelength λct should not be changed (No in step S36), the laser control processor 12A returns to the process in step S34. When the target center wavelength λct should be changed (Yes in step S36), the laser control processor 12A returns to the process in step S31.

The laser control processor 12A thus controls the temperature of the semiconductor laser 132 in such a way that the average of the measured wavelengths of the pulse laser light PL3 becomes the target center wavelength λct by using the relationship between the temperature of the semiconductor laser 132 and the wavelength of the pulse laser light PL3.

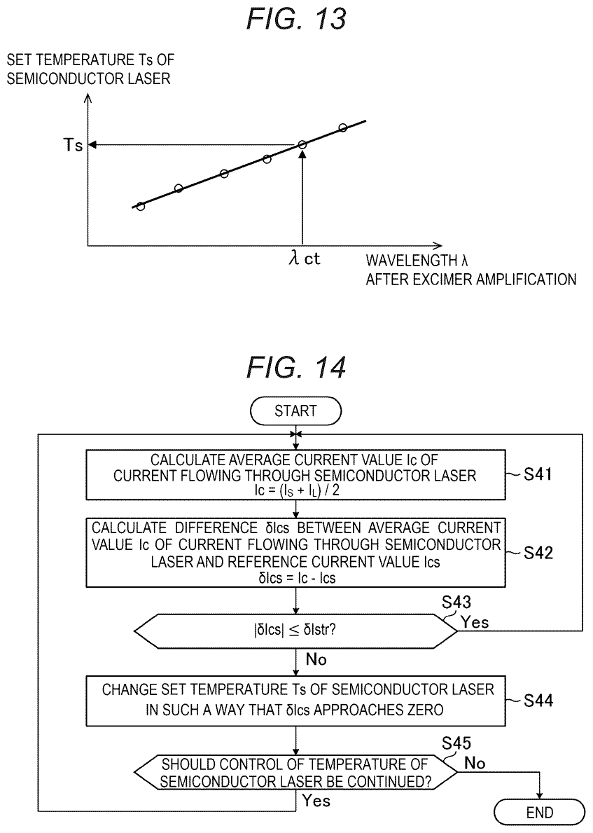

FIG. 13 is a graph showing the relationship between the temperature Ts, at which the semiconductor laser 132 is set when the current value is the reference current value Ics, and the wavelength λ after the excimer amplification. The reference current value Ics is a current value that allows the semiconductor laser 132 to undergo laser oscillation, and further allows the wavelength and performance of the semiconductor laser 132 to be maintained even when the current is changed within a range over which the wavelength is changed.

In FIG. 13, the horizontal axis represents the wavelength λ after the excimer amplification, and the vertical axis represents the set temperature Ts of the semiconductor laser 132. The laser control processor 12A may actually measure in advance the relationship between the temperature of the semiconductor laser 132 and the wavelength of the pulse laser light PL3 as the expression of the relationship in step S32, and calculate an approximate straight line or an approximate curve, such as the one shown in FIG. 13, from the measured data. Still instead, table data may be used in place of the approximate straight line or the approximate curve.

### 4.3.2 Second Example of Flowchart

FIG. 14 is a flowchart showing the procedure of processes carried out by the laser control processor 12A when the laser control processor 12A controls the temperature of the semiconductor laser 132 based on an average current value Ic.

In step S41, the laser control processor 12A calculates the average current value Ic of the current flowing through the semiconductor laser 132. That is, the laser control processor 12A calculates the average current value Ic as follows: Ic=(I_{S}+I_{L})/2.

In step S42, the laser control processor 12A calculates a difference δIcs between the average current value Ic calculated in step S41 and the reference current value Ics. That is, the laser control processor 12A calculates the difference δIcs as follows: δIcs=Ic−Ics.

In step S43, the laser control processor 12A evaluates whether the absolute value of the difference δIcs calculated in step S42 is smaller than or equal to an acceptable value δIstr. That is, the laser control processor 12A evaluates whether |δIcs| ≤δIstr is satisfied. When |δIcs|≤δIstr is satisfied (Yes in step S43), the laser control processor 12A returns to the process in step S41. When |δIcs|≤δIstr is not satisfied (No in step S43), the laser control processor 12A proceeds to the process in step S44.

In step S44, the laser control processor 12A changes the set temperature Ts of the semiconductor laser 132 in such a way that δIcs approaches zero.

In step S45, the laser control processor 12A evaluates whether the control of the temperature of the semiconductor laser 132 should be continued. When the temperature control should not be continued (No in step S45), the laser control processor 12A terminates the processes in the flowchart. When the temperature control should be continued (Yes in step S45), the laser control processor 12A returns to the process in step S41.

### 4.3.3 Effects and Advantages

When the target center wavelength has been greatly changed, the wavelength after the excimer amplification cannot be controlled in some cases only by using the current value of the current flowing through the semiconductor laser 132.

Setting the temperature of the semiconductor laser 132 as shown in FIG. 12 or 14 allows the average current value of the current caused to flow through the semiconductor laser 132 to be maintained near the reference current value Ics even when the target center wavelength is greatly changed. The most preferable value of the reference current value Ics is the value at the center of the range over which the current caused to flow through the semiconductor laser 132 can be changed. The average current value of the current caused to flow through the semiconductor laser 132 in the first embodiment is an example of the “average of a current” in the present disclosure.

As a result, even when the target wavelength of the two-wavelength spectrum is changed, the wavelength can be changed to each of the two wavelengths with high precision on a pulse basis.

### 4.4 Wavelength Conversion System

### 4.4.1 Configuration

FIG. 15 schematically shows an example of the configuration of the wavelength conversion system 108.

The wavelength conversion system 108 includes a KBBF crystal 162, an LBO crystal 164, rotary stages 166 and 168 as actuators, and a rotary stage driver 170 as a controller that controls the actuators. The term “KBBF” is expressed by a chemical formula KBe₂BO₃F₂. The term “LBO” is expressed by a chemical formula LiB₃O₅. The KBBF crystal 162 in the first embodiment is an example of the “first nonlinear crystal” in the present disclosure.

The KBBF crystal 162 is disposed on the rotary stage 166. The LBO crystal 164 is disposed on the rotary stage 168. To rotate the wavelength converters at high speed, the rotary stages 166 and 168 are each a rotary stage including a piezoelectric device. The rotary stage driver 170 controls the angle of each of the rotary stages 166 and 168.

The actuators may be heaters for controlling the temperatures of the nonlinear crystals, and the controller may be a temperature controller.

### 4.4.2 Operation

The pulse laser light having been input to the wavelength conversion system 108 enters the LBO crystal 164. The LBO crystal 164 converts the pulse laser light having the wavelength of about 773.6 nm into pulse laser light having a wavelength of about 386.8 nm, which is second harmonic light of the incident pulse laser light.

The KBBF crystal 162 converts the pulse laser light output from the LBO crystal 164 and having the wavelength of about 386.8 nm into pulse laser light having the wavelength of about 193.4 nm, which is second harmonic light of the incident pulse laser light.

The converted pulse laser light having the wavelength of about 193.4 nm is output from the wavelength conversion system 108.

In the case of one-wavelength oscillation, the laser control processor 12A controls the angle of incidence of the pulse laser light to be incident on each of the KBBF crystal 162 and the LBO crystal 164 in such a way that the wavelength conversion efficiency is maximized at the target wavelength λt, that is, phase matching is achieved. The angles of incidence of the pulse laser light to be incident on the KBBF crystal 162 and the LBO crystal 164 are controlled by rotation of the rotary stages 166 and 168.

FIG. 16 shows graphs indicating the relationship between the wavelength λ after the wavelength conversion and wavelength conversion efficiency η. In FIG. 16, the horizontal axis represents the wavelength λ after the wavelength conversion, and the vertical axis represents the wavelength conversion efficiency η. FIG. 16 shows a wavelength conversion efficiency curve WCE (KBBF) for the KBBF crystal 162 and a wavelength conversion efficiency curve WCE (LBO) for the LBO crystal 164. The wavelength conversion efficiency of the KBBF crystal 162, which is the downstream nonlinear crystal, decreases at wavelengths that deviate to some extent from the wavelength λ after the wavelength conversion, as shown in FIG. 16. Therefore, when the two-wavelength spectrum has a large target wavelength difference Δλt, the pulse energy of the pulse laser light converted in terms of wavelength may decrease unless the angle of incidence of the pulse laser light to be incident on the KBBF crystal 162 is controlled to achieve the phase matching on a pulse basis.

### 4.5 Nonlinear Crystal Temperature Adjustment System

### 4.5.1 Configuration

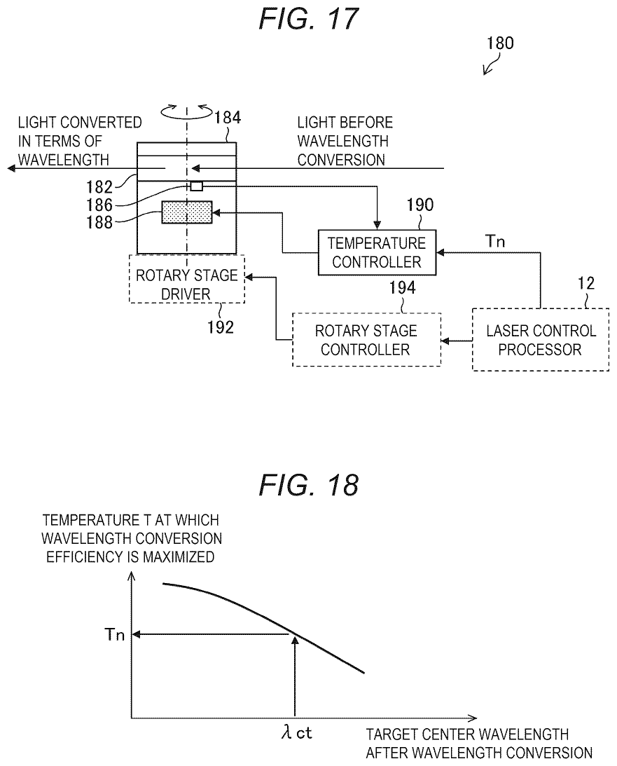

FIG. 17 schematically shows an example of the configuration of a nonlinear crystal temperature adjustment system 180. The temperature adjustment system 180 shown in FIG. 17 can be used to adjust the temperatures of the KBBF crystal 162 and the LBO crystal 164 in FIG. 15.

The nonlinear crystal temperature adjustment system 180 includes a nonlinear crystal 182, a nonlinear crystal holder 184, a temperature sensor 186, a heater 188, and a temperature controller 190.

The nonlinear crystal 182 is fixed to the nonlinear crystal holder 184. The temperature sensor 186 is disposed near the nonlinear crystal 182 in the nonlinear crystal holder 184. The heater 188 is disposed within the nonlinear crystal holder 184.

The nonlinear crystal temperature adjustment system 180 may further include a rotary stage 192, which controls the angle of incidence of the pulse laser light to be incident on the nonlinear crystal 182, and a rotary stage controller 194, which controls the rotary stage 192.

### 4.5.2 Operation

The temperature controller 190 receives data on a temperature Tn of the nonlinear crystal 182 from the laser control processor 12A. The temperature controller 190 controls the power applied to the heater 188 in such a way that the temperature of the nonlinear crystal 182 becomes the received temperature Tn to cause the temperature of the nonlinear crystal 182 to approach Tn.

The laser control processor 12A determines and sets the temperature Tn of the nonlinear crystal 182 from the target wavelength λt based on data on the relationship between the wavelength and temperature that maximizes the wavelength conversion efficiency of the nonlinear crystal 182. The data may be measured in advance, and an approximate curve may be determined based on the measured data and stored, or the measured data may be stored as table data.

When the phase matching cannot be achieved by the temperature control alone, the phase matching may be achieved by controlling the angle of incidence of the pulse laser light to be incident on the nonlinear crystal 182 with the rotary stage 192.

FIG. 18 shows the data on the relationship between the wavelength and temperature that maximizes the wavelength conversion efficiency of the nonlinear crystal 182, which is stored by the laser control processor 12A, and is a graph showing the relationship between the target center wavelength after the wavelength conversion and a temperature T, at which the wavelength conversion efficiency is maximized. In FIG. 18, the horizontal axis represents the target center wavelength after the wavelength conversion, and the vertical axis represents the temperature T, at which the wavelength conversion efficiency is maximized. The temperature at which the wavelength conversion efficiency is maximized is Tn when the target center wavelength after the wavelength conversion is λct, as shown in FIG. 18.

### 4.5.3 Others

When the nonlinear crystal 182 is a KBBF crystal or an LBO crystal, it does not need to be disposed in a cell. On the other hand, when the nonlinear crystal 182 is a CLBO crystal, which is hygroscopic, it is necessary to dispose the nonlinear crystal 182 and the nonlinear crystal holder 184 in a cell that is not shown and control the temperature of the interior of the cell to fall within a range, for example, from 120 to 170° C. The term “CLBO” is expressed by a chemical formula CsLiB₆O₁₀.

### 4.6 Wavelength Conversion System

### 4.6.1 Example of Flowchart

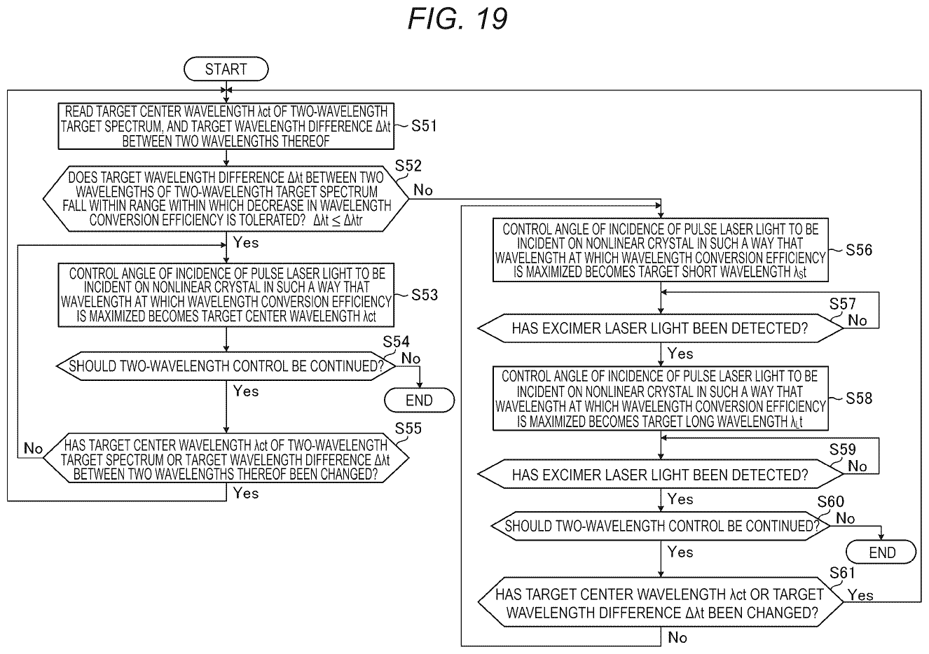

FIG. 19 is a flowchart showing the procedure of processes carried out by the laser control processor 12A when the laser control processor 12A controls the wavelength conversion system 108.

In step S51, the laser control processor 12A reads the target center wavelength λct of the two-wavelength spectrum and the target wavelength difference λλt between the two wavelengths thereof, which are calculated from the two-wavelength parameters received from the exposure control processor 310.

In step S52, the laser control processor 12A evaluates whether the target wavelength difference Δλt between the two wavelengths of the two-wavelength spectrum acquired in step S51 falls within a range Δλtr, within which a decrease in wavelength conversion efficiency is tolerated. That is, the laser control processor 12A evaluates whether Δλt≤Δλtr is satisfied. When ΔλtΔλtr is satisfied (Yes in step S52), the laser control processor 12A proceeds to the process in step S53. When Δλt≤Δλtr is not satisfied (No in step S52), the laser control processor 12A proceeds to the process in step S56.

In step S53, the laser control processor 12A controls the angle of incidence of the pulse laser light to be incident on each of the KBBF crystal 162 and the LBO crystal 164 in such a way that the wavelength at which the wavelength conversion efficiency is maximized becomes the target center wavelength λct acquired in step S51. That is, the laser control processor 12A controls the rotary stages 166 and 168 in such a way that the KBBF crystal 162 and the LBO crystal 164 achieve the phase matching at the target center wavelength λct.

In step S54, the laser control processor 12A evaluates whether the two-wavelength control should be continued. When the two-wavelength control should be continued (Yes in step S54), the laser control processor 12A proceeds to the process in step S55. When the two-wavelength control should not be continued (No in step S54), the laser control processor 12A terminates the processes in the flowchart.

In step S55, the laser control processor 12A evaluates whether the target center wavelength λct of the two-wavelength spectrum or the target wavelength difference Δλt between the two wavelengths thereof has been changed. When the target center wavelength λct of the two-wavelength spectrum or the target wavelength difference Δλt between the two wavelengths thereof has not been changed (No in step S55), the laser control processor 12A returns to the process in step S53. When the target center wavelength λct of the two-wavelength spectrum or the target wavelength difference Δλt between the two wavelengths thereof has been changed (Yes in step S55), the laser control processor 12A returns to the process in step S51.

In step S56, the laser control processor 12A controls the angle of incidence of the pulse laser light to be incident on each of the KBBF crystal 162 and the LBO crystal 164 in such a way that the wavelength at which the wavelength conversion efficiency is maximized becomes the target short wavelength λ_{S}t.

In step S57, the laser control processor 12A evaluates whether the excimer laser light has been detected by the spectrum monitor 126. When the excimer laser light has not been detected (No in step S57), the laser control processor 12A waits until the excimer laser light is detected. When the excimer laser light has been detected (Yes in step S57), the laser control processor 12A proceeds to the process in step S58.

In step S58, the laser control processor 12A controls the angle of incidence of the pulse laser light to be incident on each of the KBBF crystal 162 and the LBO crystal 164 in such a way that the wavelength at which the wavelength conversion efficiency is maximized becomes the target long wavelength λ_{L}t.

In step S59, the laser control processor 12A evaluates whether the excimer laser light has been detected by the spectrum monitor 126. When the excimer laser light has not been detected (No in step S59), the laser control processor 12A waits until the excimer laser light is detected. When the excimer laser light has been detected (Yes in step S59), the laser control processor 12A proceeds to the process in step S60.

In step S60, the laser control processor 12A evaluates whether the two-wavelength control should be continued. When the two-wavelength control should be continued (Yes in step S60), the laser control processor 12A proceeds to the process in step S61. When the two-wavelength control should not be continued (No in step S60), the laser control processor 12A terminates the processes in the flowchart.

In step S61, the laser control processor 12A evaluates whether the target center wavelength λct of the two-wavelength spectrum or the target wavelength difference Δλt between the two wavelengths thereof has been changed. When the target center wavelength λct of the two-wavelength spectrum or the target wavelength difference Δλt between the two wavelengths thereof has not been changed (No in step S61), the laser control processor 12A returns to the process in step S56. When the target center wavelength λct of the two-wavelength spectrum or the target wavelength difference Δλt between the two wavelengths thereof has been changed (Yes in step S61), the laser control processor 12A returns to the process in step S51.

### 4.6.2 Operation

The laser control processor 12A evaluates whether the target wavelength difference Δλt between the two wavelengths of the two-wavelength spectrum falls within the range within which a decrease in wavelength conversion efficiency is tolerated, as shown in FIG. 19. The target wavelength difference Δλt should fall, for example, within a range from 1 μm to 2 μm. Based on the result of the evaluation, the angle of incidence of the pulse laser light to be incident on the KBBF crystal 162 and the LBO crystal 164, which are the wavelength converters, is controlled differently.

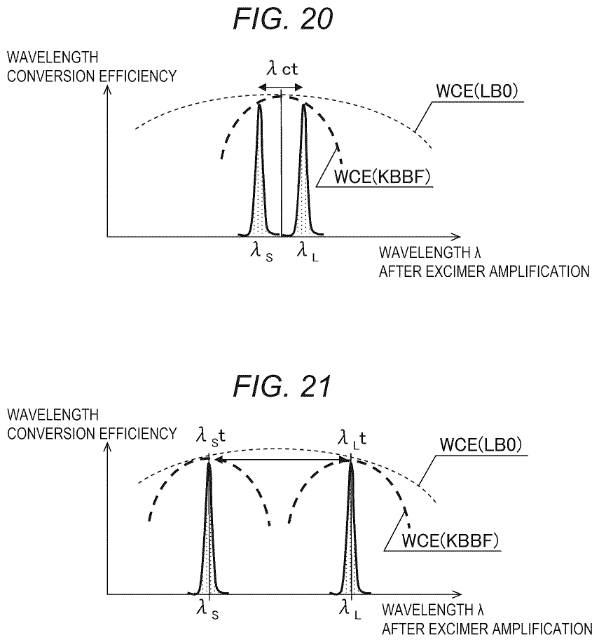

FIGS. 20 and 21 are graphs showing the relationship between the wavelength λ after the excimer amplification and the wavelength conversion efficiency. In FIGS. 20 and 21, the horizontal axis represents the wavelength λ after the excimer amplification, and the vertical axis represents the wavelength conversion efficiency.

When the target wavelength difference Δλt between the two wavelengths of the two-wavelength spectrum falls within the range within which a decrease in wavelength conversion efficiency is suppressed, the angle of incidence of the pulse laser light to be incident on each of the KBBF crystal 162 and the LBO crystal 164 is so controlled that the highest wavelength conversion efficiency is achieved at the target center wavelength λct of the two-wavelength spectrum, as shown in FIG. 20.

On the other hand, when the target wavelength difference Δλt between the two wavelengths of the two-wavelength spectrum is greater than the range within which a decrease in wavelength conversion efficiency is suppressed, the angle of incidence of the pulse laser light to be incident on the KBBF crystal 162, which is the nonlinear crystal disposed at the most downstream position, is at least so controlled that the conversion efficiency is maximized at each of the target short wavelength λ_{S}t and the target long wavelength λ_{L}t on a pulse basis synchronously with each pulse, as shown in FIG. 21.

When the target wavelength difference Δλt between the two wavelengths of the two-wavelength spectrum is even greater, the angle of incidence of the pulse laser light to be incident on the LBO crystal 164, which is the second nonlinear crystal next to the most downstream nonlinear crystal, may also be so controlled that the conversion efficiency is maximized at each of the target short wavelength λ_{S}t and the target long wavelength λ_{L}t.

### 4.6.3 Effects and Advantages

When the target wavelength difference Δλt falls within the tolerable range, changes in wavelength conversion efficiency are suppressed, so that the pulse energy and the wavelengths λ_{S} and λ_{L} of the two-wavelength spectrum are controlled with high precision on a pulse basis.

When the target wavelength difference Δλt≤1 to 2 μm is satisfied, increasing the depth of focus allows a margin for formation and processing of a contact-hole photoresist pattern to be provided.

When the target wavelength difference Δλt>1 to 2 μm is satisfied, the two-wavelength exposure can also be used to form a thick photoresist film in a 3D semiconductor manufacturing process.

### 5. Second Embodiment

A case where the target exposure spectrum is a multiple-wavelength spectrum will be described. The description will be made with reference to the wavelength control in which a target wavelength λ(k)t is periodically changed.

### 5.1 Configuration

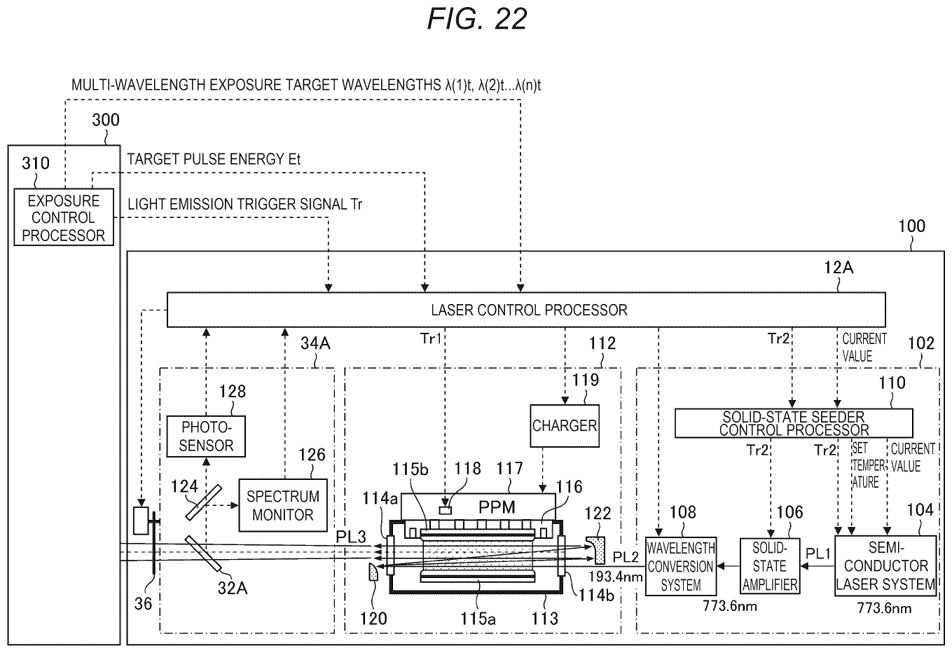

FIG. 22 shows the configuration of an exposure system according to a second embodiment. The exposure system includes a laser apparatus 100 and an exposure apparatus 300.

The exposure control processor 310 of the exposure apparatus 300 transmits multi-wavelength exposure target wavelengths λ(1)t, λ(2)t, . . . , and λ(n)t to the laser control processor 12A. The laser control processor 12A controls the laser apparatus 100 in accordance with the parameters described above.

### 5.2 Flowchart Executed by Laser Control Processor

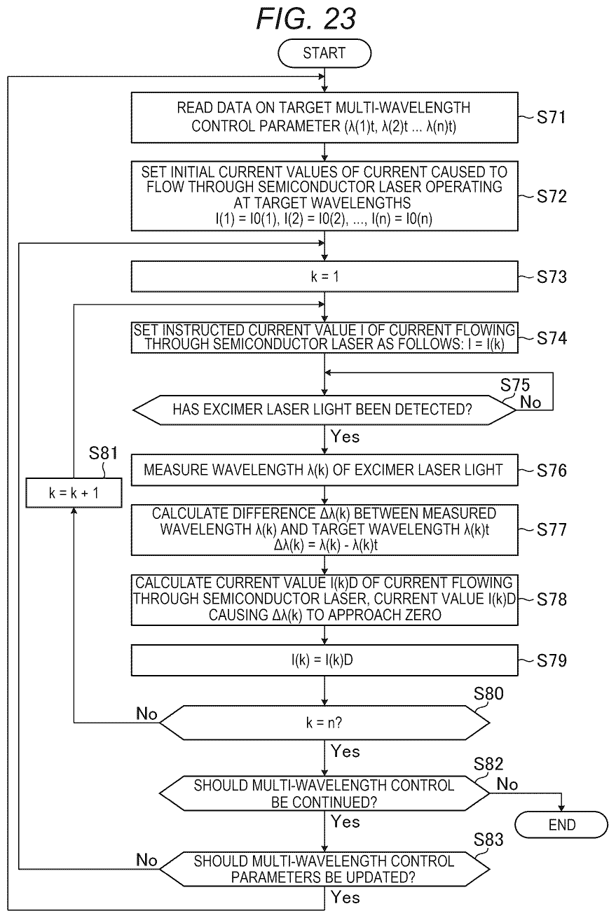

The following description will be made with reference to the wavelength control in which the target wavelength λ(k)t is periodically changed. FIG. 23 is a flowchart showing the procedure of processes carried out by the laser control processor 12A in the second embodiment. The procedure of the processes carried out by the laser control processor 12A in the second embodiment is an example of the “method for controlling a wavelength of a laser apparatus” in the present disclosure.

In step S71, the laser control processor 12A reads target multi-wavelength control parameter data from the exposure control processor 310. The target multi-wavelength control parameter data include λ(1)t, λ(2)t, . . . , and λ(n)t.

In step S72, the laser control processor 12A sets current values I(1), I(2), . . . , and I(n) of the current caused to flow at the target wavelengths through the semiconductor laser 132 at initial values I0(1), I0(2), . . . , and I0(n) of the current values, respectively. That is, the laser control processor 12A sets the current values as follows:

$$I ( 1 ) = I 0 ( 1 ) , I ( 2 ) = I 0 ( 2 ) , … , and I ( n ) = I 0 ( n ) .$$

In step S73, the laser control processor 12A initializes a variable k at one. That is, the laser control processor 12A sets the variable k as follows: k=1.

In step S74, the laser control processor 12A sets an instructed current value I of the current flowing through the semiconductor laser 132 at I(k). That is, the laser control processor 12A sets the instructed current value I as follows: I=I(k).

In step S75, the laser control processor 12A evaluates whether the excimer laser light has been detected by the spectrum monitor 126. When the excimer laser light has not been detected (No in step S75), the laser control processor 12A waits until the excimer laser light is detected. When the excimer laser light has been detected (Yes in step S75), the laser control processor 12A proceeds to the process in step S76.

In step S76, the laser control processor 12A causes the spectrum monitor 126 to measure the wavelength λ(k) of the excimer laser light.

In step S77, the laser control processor 12A calculates a difference Δλ(k) between the wavelength λ(k) measured in step S76 and the target wavelength λ(k)t. That is, the laser control processor 12A calculates the difference Δλ(k) as follows: Δλ(k)=λ(k)−λ(k)t.

In step S78, the laser control processor 12A calculates a current value I(k)D of the current flowing through the semiconductor laser 132, the value I(k)D causing the difference Δλ(k) calculated in step S77 to approach zero.

In step S79, the laser control processor 12A sets a current value I(k) of the current caused to flow through the semiconductor laser 132 at the current value I(k)D calculated in step S78. That is, the laser control processor 12A sets the current value I(k) as follows: I(k)=I(k)D.

In step S80, the laser control processor 12A evaluates whether k=n. When k=n is not satisfied (No in step S80), the laser control processor 12A proceeds to the process in step S81. When k=n is satisfied (Yes in step S80), the laser control processor 12A proceeds to the process in step S82.

In step S81, the laser control processor 12A increments the variable k. That is, the laser control processor 12A sets the variable k as follows: k=k+1. The laser control processor 12A then returns to the process in step S74. The wavelength control is thus performed at each of the target wavelengths until k changes from 1 to n.

In step S82, the laser control processor 12A evaluates whether the multi-wavelength control should be continued. When the multi-wavelength control should be continued (Yes in step S82), the laser control processor 12A proceeds to the process in step S83. When the multi-wavelength control should not be continued (No in step S82), the laser control processor 12A terminates the processes in the flowchart.

In step S83, the laser control processor 12A evaluates whether the multi-wavelength control parameters should be updated. When the multi-wavelength control parameters should not be updated (No in step S83), the laser control processor 12A proceeds to the process in step S73. When the multi-wavelength control parameters should be updated (Yes in step S83), the laser control processor 12A returns to the process in step S71.

As described above, to output the laser light having the target wavelength λ(k)t, the laser apparatus 100 controls the current value I(k) of the current flowing through the semiconductor laser 132 based on the measured value of the wavelength λ(k) of the laser light output at the most recent target wavelength λ(k)t.

### 5.3 Control of Temperature of Semiconductor Laser

### 5.3.1 First Example of Flowchart

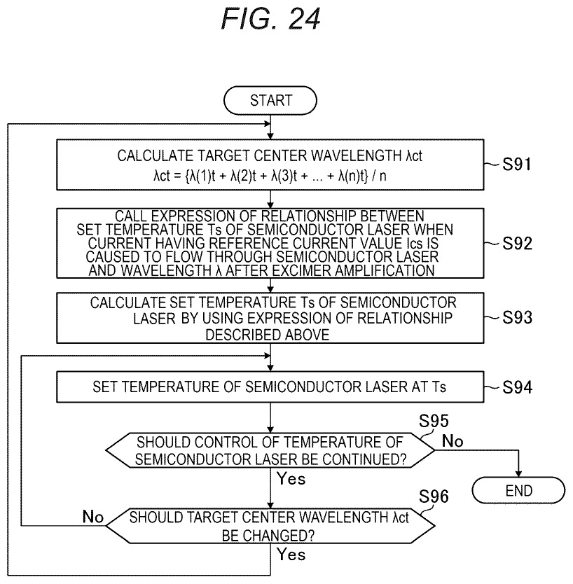

FIG. 24 is a flowchart showing the procedure of processes carried out by the semiconductor laser control processor 134 when the semiconductor laser control processor 134 controls the temperature of the semiconductor laser 132 based on the target center wavelength λct.

In step S91, the semiconductor laser control processor 134 calculates the target center wavelength λct. That is, the semiconductor laser control processor 134 calculates the target center wavelength λct as follows: λct={λ(1)t+λ(2)t+λ(3)t+ . . . +λ(n)t}/n.

Steps S92 to S96 after step S91 are the same as steps S32 to S36 shown in FIG. 12, respectively.

### 5.3.2 Second Example of Flowchart

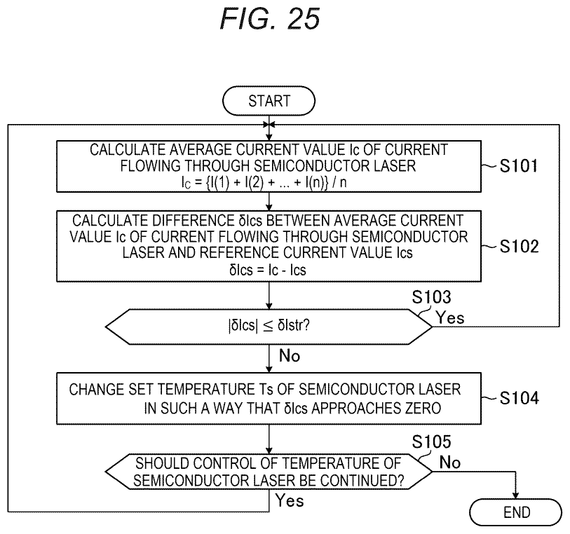

FIG. 25 is a flowchart showing the procedure of processes carried out by the semiconductor laser control processor 134 when the semiconductor laser control processor 134 controls the temperature of the semiconductor laser 132 based on the average current value Ic.

In step S101, the laser control processor 12A calculates the average current value Ic of the current flowing through the semiconductor laser 132. That is, the laser control processor 12A calculates the average current value Ic as follows: I_{C}={I(1)+I(2)+ . . . +I(n)}/n.

Steps S102 to S105 after step S101 are the same as steps S42 to S45 shown in FIG. 14, respectively.

### 5.3.3 Effects and Advantages

When the target center wavelength has been greatly changed, the wavelength after the excimer amplification cannot be controlled in some cases only by using the current value of the current flowing through the semiconductor laser.

Setting the temperature of the semiconductor laser 132 allows the average current value of the current caused to flow through the semiconductor laser 132 to be maintained near the reference current value Ics even when the target center wavelength is greatly changed, as shown in FIGS. 24 and 25.

As a result, even when the target wavelength of the multi-wavelength spectrum is changed, the wavelength can be changed to each of the multiple wavelengths with high precision on a pulse basis.

### 5.4 Wavelength Conversion System

### 5.4.1 Example of Flowchart

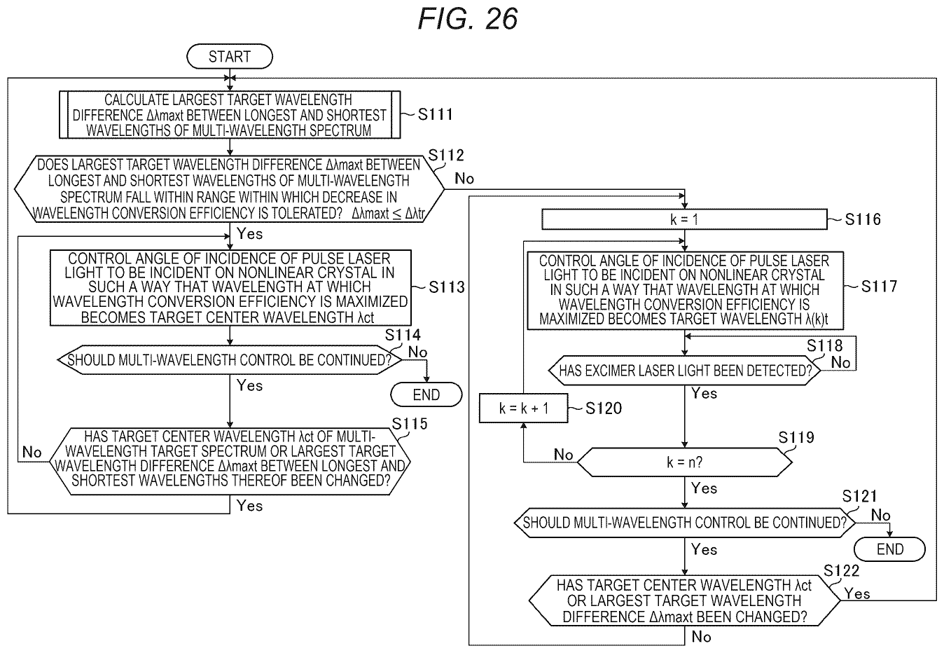

FIG. 26 is a flowchart showing the procedure of processes carried out by the laser control processor 12A when the laser control processor 12A controls the wavelength conversion system 108.

In step S111, the laser control processor 12A calculates a largest target wavelength difference Δλmaxt of the multi-wavelength spectrum.

In step S112, the laser control processor 12A evaluates whether the largest target wavelength difference Δλmaxt between the longest and shortest wavelengths of the multi-wavelength spectrum falls within the range Δλtr, within which a decrease in wavelength conversion efficiency is tolerated. That is, the laser control processor 12A evaluates whether Δλmaxt≤Δλtr is satisfied. When Δλmaxt≤Δλtr is satisfied (Yes in step S112), the laser control processor 12A proceeds to the process in step S113. When Δλmaxt≤Δλtr is not satisfied (No in step S112), the laser control processor 12A proceeds to the process in step S116.

In step S113, the laser control processor 12A controls the angle of incidence of the pulse laser light to be incident on each of the KBBF crystal 162 and the LBO crystal 164 in such a way that the wavelength at which the conversion efficiency is maximized becomes the target center wavelength λct. That is, the laser control processor 12A controls the rotary stages 166 and 168 in such a way that the KBBF crystal 162 and the LBO crystal 164 achieve the phase matching at the target center wavelength λct.

In step S114, the laser control processor 12A evaluates whether the multi-wavelength control should be continued. When the multi-wavelength control should be continued (Yes in step S114), the laser control processor 12A proceeds to the process in step S115. When the multi-wavelength control should not be continued (No in step S114), the laser control processor 12A terminates the processes in the flowchart.

In step S115, the laser control processor 12A evaluates whether the target center wavelength λct of the multi-wavelength spectrum or the largest target wavelength difference Δλmaxt between the longest and shortest wavelengths thereof has been changed. When the target center wavelength λct of the multi-wavelength spectrum or the largest target wavelength difference Δλmaxt between the longest and shortest wavelengths thereof has not been changed (No in step S115), the laser control processor 12A returns to the process in step S113. When the target center wavelength λct of the multi-wavelength spectrum or the largest target wavelength difference Δλmaxt between the longest and shortest wavelengths thereof has been changed (Yes in step S115), the laser control processor 12A returns to the process in step S111.

In step S116, the laser control processor 12A initializes the variable k at one. That is, the laser control processor 12A sets the variable k as follows: k=1.

In step S117, the laser control processor 12A controls the angle of incidence of the pulse laser light to be incident on each of the KBBF crystal 162 and the LBO crystal 164 in such a way that the wavelength at which the wavelength conversion efficiency is maximized becomes the target wavelength Mk)t.

In step S118, the laser control processor 12A evaluates whether the excimer laser light has been detected by the spectrum monitor 126. When the excimer laser light has not been detected (No in step S118), the laser control processor 12A waits until the excimer laser light is detected. When the excimer laser light has been detected (Yes in step S118), the laser control processor 12A proceeds to the process in step S119.

In step S119, the laser control processor 12A evaluates whether k=n. When k=n is not satisfied (No in step S119), the laser control processor 12A proceeds to the process in step S120. When k=n is satisfied (Yes in step S119), the laser control processor 12A proceeds to the process in step S121.

In step S120, the laser control processor 12A increments the variable k. That is, the laser control processor 12A sets the variable k as follows: k=k+1. The laser control processor 12A then returns to the process in step S117. The angle of incidence of the pulse laser light to be incident on each of the nonlinear crystals is therefore controlled for each target wavelength until k changes from 1 to n.

In step S121, the laser control processor 12A evaluates whether the multi-wavelength control should be continued. When the multi-wavelength control should be continued (Yes in step S121), the laser control processor 12A proceeds to the process in step S122. When the multi-wavelength control should not be continued (No in step S121), the laser control processor 12A terminates the processes in the flowchart.

In step S122, the laser control processor 12A evaluates whether the target center wavelength λct of the multi-wavelength spectrum or the largest target wavelength difference Δλmaxt between the longest and shortest wavelengths thereof has been changed. When the target center wavelength λct of the multi-wavelength spectrum or the largest target wavelength difference Δλmaxt between the longest and shortest wavelengths thereof has not been changed (No in step S122), the laser control processor 12A returns to the process in step S116. When the target center wavelength λct of the multi-wavelength spectrum or the largest target wavelength difference Δλmaxt between the longest and shortest wavelengths thereof has been changed (Yes in step S122), the laser control processor 12A returns to the process in step S111.

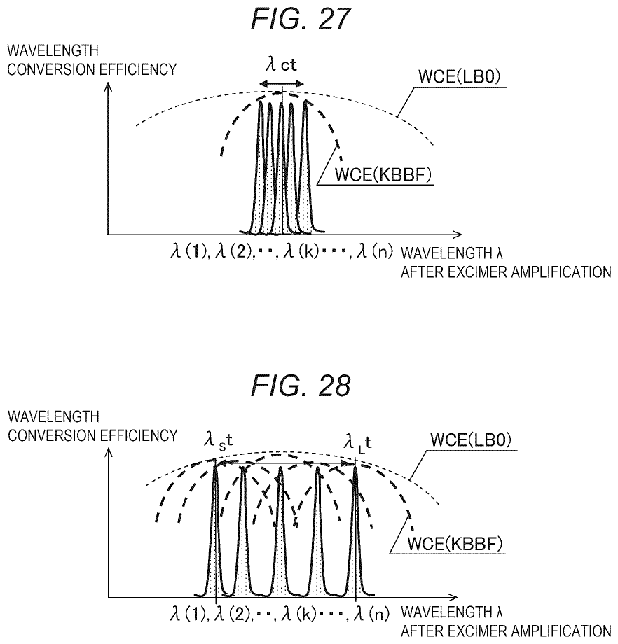

FIGS. 27 and 28 are graphs showing the relationship between the wavelength λ after the excimer amplification and the wavelength conversion efficiency η. In FIGS. 27 and 28, the horizontal axis represents the wavelength λ after the excimer amplification, and the vertical axis represents the wavelength conversion efficiency.

When the largest target wavelength difference Δλmaxt between the longest and shortest wavelengths of the multi-wavelength spectrum falls within the range within which a decrease in wavelength conversion efficiency is suppressed, the angle of incidence of the pulse laser light to be incident on each of the KBBF crystal 162 and the LBO crystal 164 is so controlled that the wavelength conversion efficiency is maximized at the target center wavelength λct of the multi-wavelength spectrum, as shown in FIG. 27.

On the other hand, when the largest target wavelength difference Δλmaxt between the longest and shortest wavelengths of the multi-wavelength spectrum is greater than the range within which a decrease in wavelength conversion efficiency is suppressed, the angle of incidence of the pulse laser light to be incident on the KBBF crystal 162, which is the nonlinear crystal disposed at the most downstream position, is at least so controlled that the conversion efficiency is maximized at each of the target wavelengths λ(k)t on a pulse basis synchronously with each pulse, as shown in FIG. 28.

When the largest target wavelength difference Δλmaxt between the longest and shortest wavelengths of the multi-wavelength spectrum is even greater, the angle of incidence of the pulse laser light to be incident on the LBO crystal 164, which is the second nonlinear crystal next to the most downstream nonlinear crystal, may also be so controlled that the conversion efficiency is maximized at each target wavelength λ(k)t.

### 5.4.2 Example of Flowchart

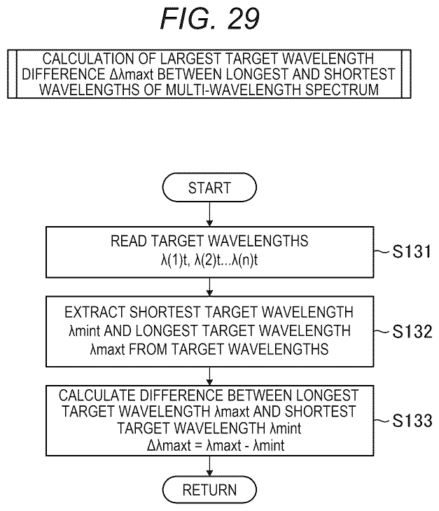

FIG. 29 is a flowchart showing the procedure of the processes in step S111 in FIG. 26.

In step S131, the laser control processor 12A reads each target wavelength from the exposure control processor 310. That is, the laser control processor 12A reads λ(1)t, λ(2)t, . . . , and λ(n)t.

In step S132, the laser control processor 12A extracts a shortest target wavelength λmint and a longest target wavelength λmaxt from the target wavelengths.

In step S133, the laser control processor 12A calculates the difference Δλmaxt between the longest target wavelength λmaxt and the shortest target wavelength λmint. That is, the laser control processor 12A calculates the difference Δλmaxt as follows: Δλmaxt=λmaxt−λmint.

The laser control processor 12A then terminates the processes in the flowchart and proceeds to the process in step S112 in FIG. 26.

### 6. Third Embodiment

### 6.1 Operation in Two-Wavelength Exposure

### 6.1.1 Example of Flowchart

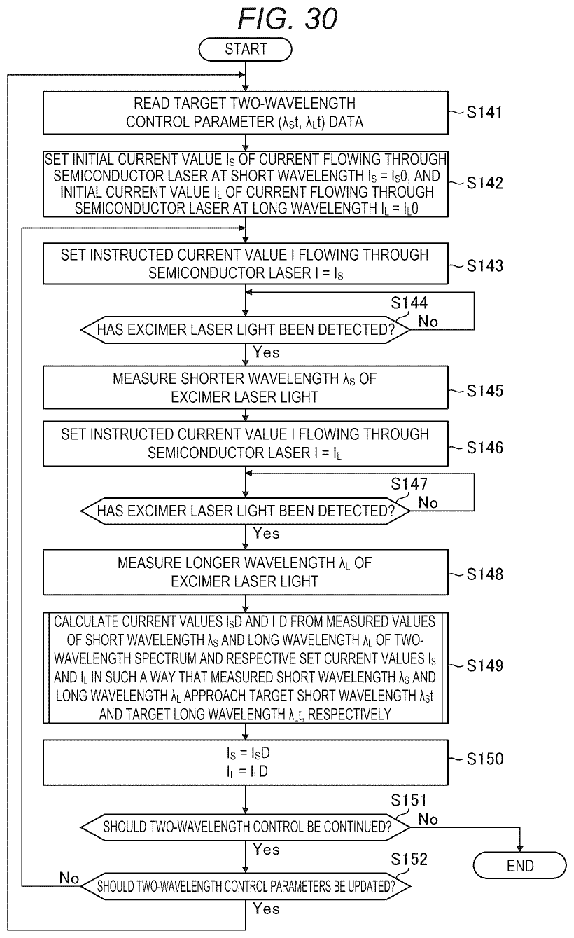

FIG. 30 is a flowchart showing the procedure of processes carried out by the laser control processor 12A in the two-wavelength exposure in a third embodiment.

Steps S141 to S145 are the same as steps S11 to S15 shown in FIG. 7, respectively. The processes in steps S143 to S145 are processes of the wavelength measurement and control at the short wavelength.

Steps S146 to S148 are the same as steps S19 to S21 shown in FIG. 7, respectively. The processes in steps S146 to S148 are processes of the wavelength measurement and control at the long wavelength.

In step S149, the laser control processor 12A uses the measured values of the short wavelength λ_{S} and the long wavelength λ_{L} of the two-wavelength spectrum, and the respective set current values I_{S} and I_{L}, to calculate the current values I_{S}D and I_{L}D, which cause the measured short wavelength λ_{S} and long wavelength λ_{L} to approach the target short wavelength λ_{S}t and the target long wavelength λ_{L}t, respectively.

In step S150, the laser control processor 12A sets the set current value I_{S} of the current caused to flow through the semiconductor laser 132 when the target wavelength is the short wavelength and the set current value I_{L} of the current caused to flow through the semiconductor laser 132 when the target wavelength is the long wavelength at the current values I_{S}D and I_{L}D calculated in step S149, respectively. That is, the laser control processor 12A sets the current values I_{S} and I_{L} as follows: I_{S}=I_{S}D; and I_{L}=I_{L}D.

As described above, when the pulse laser light having the target short wavelength λ_{S}t is output, the laser control processor 12A controls the current value I_{S} of the current flowing through the semiconductor laser 132 based also on the measured value of the wavelength λ_{S} of the latest pulse laser light output at the same target short wavelength λ_{S}t and the measured value of the wavelength λ_{L} of the latest pulse laser light output at the target long wavelength λ_{L}t different from the target short wavelength λ_{S}t. Furthermore, when the pulse laser light having the target long wavelength λ_{L}t is output, the laser control processor 12A controls the current value I_{L} of the current flowing through the semiconductor laser 132 based also on the measured value of the wavelength λ_{L} of the latest pulse laser light output at the same target long wavelength λ_{L}t and the measured value of the wavelength λ_{S} of the latest pulse laser light output at the target short wavelength λ_{S}t different from the target long wavelength λ_{L}t.

In step S151, the laser control processor 12A evaluates whether the two-wavelength control should be continued. When the two-wavelength control should be continued (Yes in step S151), the laser control processor 12A proceeds to the process in step S152. When the two-wavelength control should not be continued (No in step S151), the laser control processor 12A terminates the processes in the flowchart.

In step S152, the laser control processor 12A evaluates whether the two-wavelength control parameters should be updated. When the two-wavelength control parameters should not be updated (No in step S152), the laser control processor 12A returns to the process in step S143. When the two-wavelength control parameters should be updated (Yes in step S152), the laser control processor 12A returns to the process in step S141.

### 6.1.2 Example of Flowchart

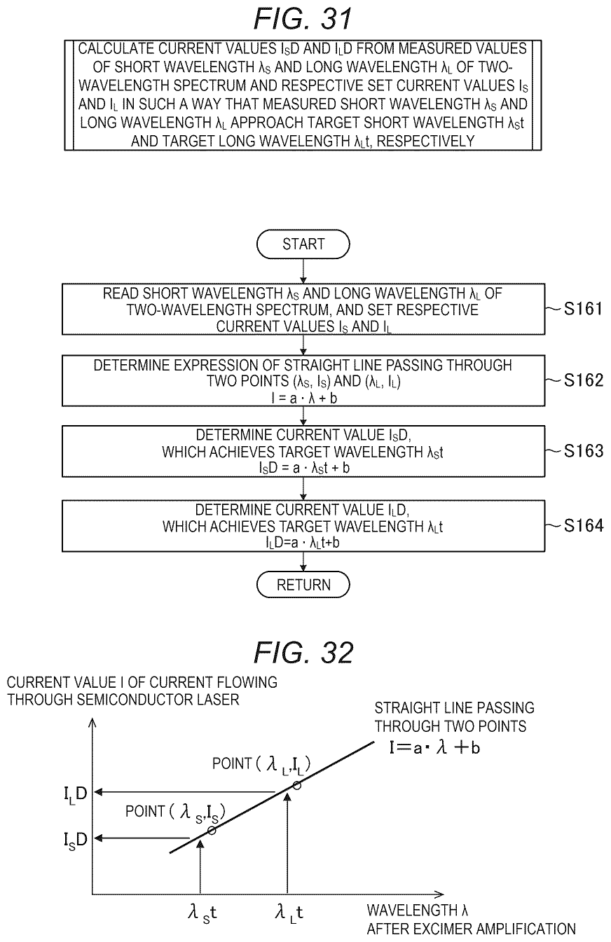

FIG. 31 is a flowchart showing the procedure of the process in step S149 in FIG. 30.

In step S161, the laser control processor 12A reads the measured values of the short wavelength λ_{S} and the long wavelength λ_{L} of the two-wavelength spectrum, and the respective set current values I_{S} and I_{L}.

In step S162, the laser control processor 12A determines the expression of the straight line passing through the two points (λ_{S}, I_{S}) and (λ_{L}, I_{L}). That is, the laser control processor 12A determines I=a·λ+b with the gradient a and the intercept b being constants.

The relationship between the oscillation wavelength λ, at which the semiconductor laser 132 operates, and the current value I of the current flowing through the semiconductor laser 132 can be expressed as a linear approximation. The gradient a and the intercept b can be determined by a=(I_{L}−I_{S})/(λ_{L}−λ_{S}) and the intercept b=I_{S}−a·λ_{S}.

In step S163, the laser control processor 12A determines the current value I_{S}D, which achieves the target short wavelength λ_{S}t, from the expression of the straight line determined in step S162. That is, the laser control processor 12A determines the current value I_{S}D as follows: I_{S}D=a·λ_{S}t+b.

In step S164, the laser control processor 12A determines the current value I_{L}D, which achieves the target long wavelength λ_{L}t, from the expression of the straight line determined in step S162. That is, the laser control processor 12A determines the current value I_{L}D as follows: I_{L}D=a·λ_{L}t+b.

The laser control processor 12A then terminates the processes in the flowchart and proceeds to the process in step S150 in FIG. 30.

FIG. 32 is a graph showing the relationship between the wavelength λ after the excimer amplification and the current value I of the current flowing through the semiconductor laser 132. In FIG. 32, the horizontal axis represents the wavelength λ after the excimer amplification, and the vertical axis represents the current value I of the current flowing through the semiconductor laser. FIG. 32 shows the straight line I=a·λ+b, which passes through the two points (λ_{S}, I_{S}) and (λ_{L}, I_{L}). The straight line I=a·A+b allows determination of the current value I_{S}D, which achieves the target short wavelength λ_{S}t, and the current value I_{L}D, which achieves the target long wavelength λ_{L}t.

As described above, the laser control processor 12A determines an approximate straight line representing the relationship between the current for changing the wavelength of the laser light from the semiconductor laser 132 and the wavelength of the pulse laser light from the measured value of the wavelength λ_{S} of the pulse laser light output at the target short wavelength λ_{S}t and the measured value of the wavelength λ_{L} of the pulse laser light output at the target long wavelength λ_{L}t, and controls the current values I_{S} and I_{L} of the current flowing through the semiconductor laser 132 based on the approximation straight line.

### 6.2 Operation in Multi-Wavelength Exposure

### 6.2.1 Example of Flowchart

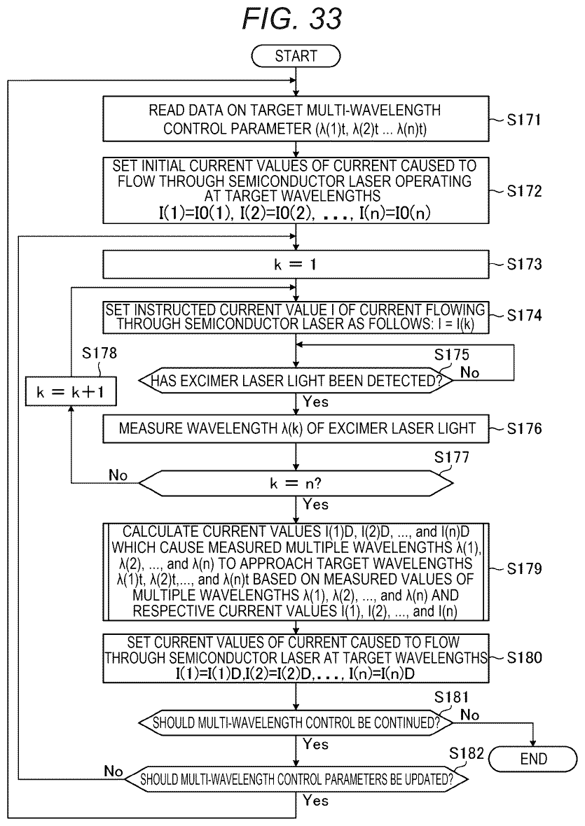

FIG. 33 is a flowchart showing the procedure of processes carried out by the laser control processor 12A in the multi-wavelength exposure in the third embodiment.

Steps S171 to S176 are the same as steps S71 to S76 shown in FIG. 23, respectively.

In step S177, the laser control processor 12A evaluates whether k=n is satisfied. When k=n is not satisfied (No in step S177), the laser control processor 12A proceeds to the process in step S178. When k=n is satisfied (Yes in step S177), the laser control processor 12A proceeds to the process in step S179.

In step S178, the laser control processor 12A increments the variable k. That is, the laser control processor 12A sets the variable k as follows: k=k+1. The laser control processor 12A then returns to the process in step S174. The processes in steps S174 to S178 are processes of the wavelength measurement and control at each target wavelength.

In step S179, the laser control processor 12A calculates current values I(1)D, I(2)D, . . . , and I(n)D, which cause the measured multiple wavelengths λ(1), λ(2), . . . , and λ(n) to approach the target wavelengths λ(1)t, λ(2)t, . . . , and λ(n)t based on the measured values of the multiple wavelengths λ(1), λ(2), . . . , and A (n) and the respective set current values I(1), I(2), . . . , and I(n).

In step S180, the laser control processor 12A sets the current value of the current caused to flow through the semiconductor laser at the target wavelengths to the current values I(1)D, I(2)D, . . . , and I(n)D calculated in step S179. That is, the laser control processor 12A sets the current values as follows: I(1)=I(1)D, I(2)=I(2)D, . . . , and I(n)=I(n)D.

In step S181, the laser control processor 12A evaluates whether the multi-wavelength control should be continued. When the multi-wavelength control should be continued (Yes in step S181), the laser control processor 12A proceeds to the process in step S182. When the multi-wavelength control should not be continued (No in step S181), the laser control processor 12A terminates the processes in the flowchart.

In step S182, the laser control processor 12A evaluates whether the multi-wavelength control parameters should be updated. When the multi-wavelength control parameters should not be updated (No in step S182), the laser control processor 12A returns to the process in step S173. When the multi-wavelength control parameters should be updated (Yes in step S182), the laser control processor 12A returns to the process in step S171.

### 6.2.2 Example of Flowchart

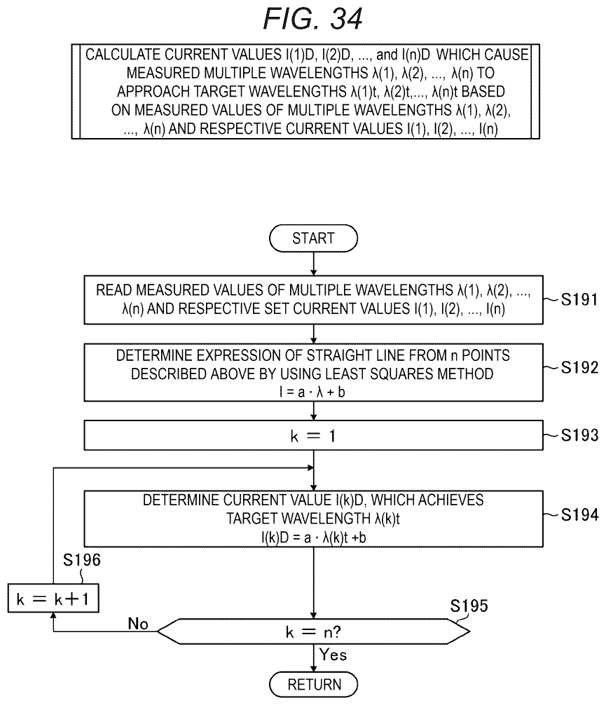

FIG. 34 is a flowchart showing the procedure of the process in step S179 in FIG. 33.

In step S191, the laser control processor 12A reads the measured values of the multiple wavelengths λ(1), λ(2), . . . , and λ(n), and the respective set current values I(1), I(2), . . . , and I(n).

In step S192, the laser control processor 12A determines the expression of the approximate straight line from n points, (λ(1), I(1)), (λ(2), I(2)), . . . , and (λ(n), I(n)), by using the least squares method. That is, the laser control processor 12A determines I=a·λ+b with the gradient a and the intercept b being constants. The relationship between the oscillation wavelength λ, at which the semiconductor laser 132 operates, and the current value I of the current flowing through the semiconductor laser 132 can be expressed as a linear approximation.

In step S193, the laser control processor 12A initializes a variable k at one. That is, the laser control processor 12A sets the variable k as follows: k=1.

In step S194, the laser control processor 12A determines the current value I(k)D, which achieves the target wavelength λ(k)t, based on the expression of the straight line determined in step S192. That is, the laser control processor 12A determines the current value I(k)D as follows: I(k)D=a·λ(k)t+b.

In step S195, the laser control processor 12A evaluates whether k=n is satisfied. When k=n is not satisfied (No in step S195), the laser control processor 12A proceeds to the process in step S196. When k=n is satisfied (Yes in step S195), the laser control processor 12A terminates the processes in the flowchart and proceeds to the process in step S180 in FIG. 33.

In step S196, the laser control processor 12A increments the variable k. That is, the laser control processor 12A sets the variable k as follows: k=k+1. The laser control processor 12A then returns to the process in step S194. The current values for the target wavelengths are thus determined until k changes from 1 to n.

As described above, when the pulse laser light having the target short wavelength λ(k)t is output, the laser control processor 12A controls the current value of the current flowing through the semiconductor laser 132 based also on the measured value of the wavelength λ(k) of the latest pulse laser light output at the same target wavelength λ(k)t and the measured value of the wavelength of the latest pulse laser light output at a target wavelength other than the target wavelength λ(k)t.

Furthermore, the laser control processor 12A determines an approximate straight line representing the relationship between the current for changing the wavelength of the laser light from the semiconductor laser 132 and the wavelength of the pulse laser light from the measured values of the wavelengths λ(1), M (2), . . . , and λ(n) of the pulse laser light output at the target wavelengths λ(1)t, λ(2)t, . . . , and λ(n)t, and controls the current value of the current flowing through the semiconductor laser 132 based on the approximation straight line.

### 7. Fourth Embodiment

### 7.1 Configuration

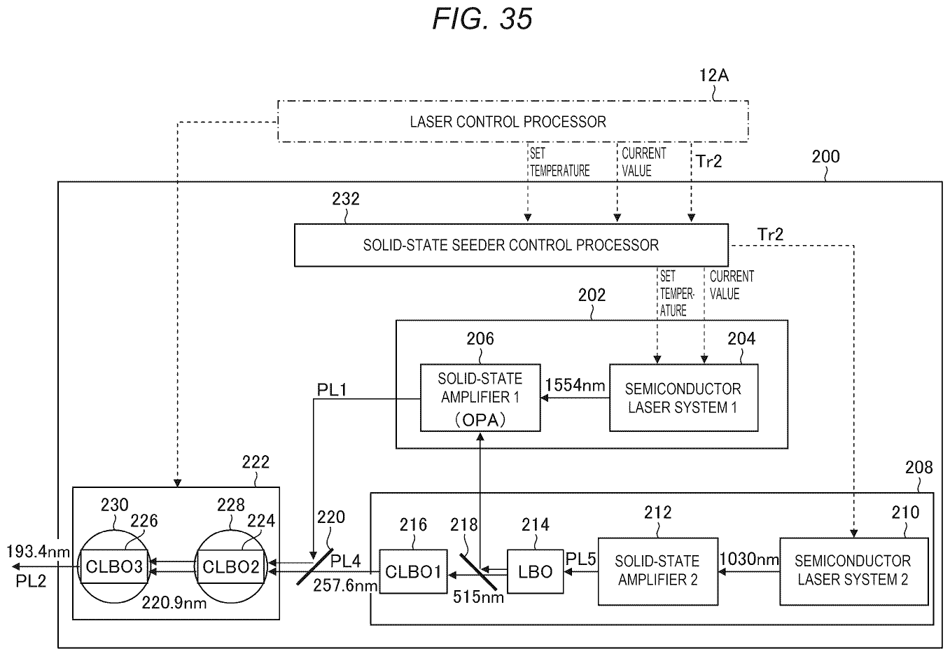

FIG. 35 schematically shows a variation of the configuration of a solid-state seeder 200. The solid-state seeder 200 shown in FIG. 35 can be used as the solid-state seeder 102 in FIG. 6.

The solid-state seeder 200 includes a first solid-state laser apparatus 202, a second solid-state laser apparatus 208, a dichroic mirror 220, a wavelength conversion system 222, and a solid-state seeder control processor 232.

The solid-state seeder 200 has a system configuration in which the wavelength conversion system 222 performs double sum frequency operation to convert pulse laser light PL1 having a wavelength of about 1554 nm and output from the first solid-state laser apparatus 202 and pulse laser light PL4 having a wavelength of about 257.6 nm and output from the second solid-state laser apparatus 208 into pulse laser light having a wavelength of about 193.4 nm.

The first solid-state laser apparatus 202 includes a first semiconductor laser system 204 and a first solid-state amplifier 206. In FIG. 35, regarding notations with numerals, for example, the “semiconductor laser system 1” and the “solid-state amplifier 1” represent the first semiconductor laser system and the first solid-state amplifier.

The first semiconductor laser system 204 can be configured in the same manner as the semiconductor laser system 104 shown in FIG. 10, but operates at an oscillation wavelength different from that at which the semiconductor laser system 104 operates. The first semiconductor laser system 204 includes the semiconductor laser 132 that performs CW oscillation in the single longitudinal mode at the wavelength of about 1554 nm, and the SOA 136.

The first solid-state amplifier 206 is an optical parametric amplifier (OPA). The OPA is made, for example, of periodically poled lithium niobate (PPLN) or periodically poled KTP or potassium titanyl phosphate crystal (PPKTP).

The first solid-state amplifier 206 has a configuration that receives pulse laser light that will be described later, has a wavelength of 1030 nm, and serves as pumping light and laser light output from the first semiconductor laser system 204 as seed light, and pulses and amplifies the seed light.

The second solid-state laser apparatus 208 includes a second semiconductor laser system 210, a second solid-state amplifier 212, an LBO crystal 214 and a first CLBO crystal 216, which are two nonlinear crystals that convert the light incident thereon in term of wavelength into fourth harmonic light, and a dichroic mirror 218. The fourth harmonic light in the fourth embodiment is an example of the “second harmonic light” in the present disclosure. The LBO crystal 214 and the first CLBO crystal 216 in the fourth embodiment are an example of the “second nonlinear crystal” in the present disclosure.

The second semiconductor laser system 210 can be configured in the same manner as the semiconductor laser system 104 shown in FIG. 10, but operates at an oscillation wavelength different from that at which the semiconductor laser system 104 operates. For example, the second semiconductor laser system 210 includes a semiconductor laser 132 that performs CW oscillation in the single longitudinal mode at a wavelength of about 1030 nm, and the SOA 136, which pulses and amplifies the laser light output from the semiconductor laser 132. The continuous-wave laser light having the wavelength of 1030 nm in the fourth embodiment is an example of the “second laser light” in the present disclosure. The semiconductor laser 132 in the fourth embodiment is an example of the “second semiconductor laser” in the present disclosure. The SOA 136 in the fourth embodiment is an example of the “second amplifier” in the present disclosure.

The second solid-state amplifier 212 includes a Yb fiber amplifier or a Yb: YAG crystal.

The dichroic mirror 218 is disposed in the optical path between the LBO crystal 214 and the first CLBO crystal 216, transmits pulse laser light having a wavelength of about 515 nm at high transmittance and reflects pulse laser light having the wavelength of about 1030 nm at high reflectance. The dichroic mirror 218 is so disposed that the pulse laser light reflected at high reflectance and having the wavelength of about 1030 nm enters the first solid-state amplifier 206 as pumping light therefor.

The wavelength conversion system 222 includes a second CLBO crystal 224, a third CLBO crystal 226, and rotary stages 228 and 230. The second CLBO crystal 224 and the third CLBO crystal 226 are disposed on the rotary stages 228 and 230, respectively, which each include a piezoelectric device, and are each configured to be capable of changing the angle of incidence of the pulse laser light to be incident on the crystal at high speed.

The dichroic mirror 220 is configured to reflect the pulse laser light having the wavelength of about 1554 nm and output from the first solid-state laser apparatus 202 at high reflectance and transmit the pulse laser light having the wavelength of about 257.6 nm and output from the second solid-state laser apparatus 208 at high transmittance, and is so disposed that the two kinds of pulse laser light coaxially enter the wavelength conversion system 222.

7.2 Operation

The laser control processor 12A fixes the oscillation wavelength at which the second solid-state laser apparatus 208 operates to 1030 nm. That is, the laser control processor 12A causes the semiconductor laser of the second semiconductor laser system 210 to perform laser oscillation by causing a current having a fixed value to flow through the semiconductor laser.

Furthermore, the laser control processor 12A causes the SOA 136 and the second solid-state amplifier 212 to pulse and amplify the CW laser light in response to the trigger signal Tr2. The second solid-state amplifier 212 outputs pulse laser light PL5 having the wavelength of 1030 nm. The pulse laser light PL5 in the fourth embodiment is an example of the “fifth pulse laser light” in the present disclosure. The pulse laser light PL5 output from the second solid-state amplifier 212 is converted by the LBO crystal 214 into second harmonic light having a wavelength of 515 nm. The second harmonic light having the wavelength of 515 nm passes through the dichroic mirror 218 at high transmittance, and is converted by the first CLBO crystal 216 into the pulse laser light PL4 having the wavelength of 257.6 nm. The second solid-state laser apparatus 208 in the fourth embodiment is an example of the “solid-state laser apparatus” in the present disclosure. The pulse laser light PL4 in the fourth embodiment is an example of the “fourth pulse laser light” in the present disclosure.

The dichroic mirror 218 reflects at high reflectance the pulse laser light having the wavelength of 1030 nm that the LBO crystal 214 could not convert into the second harmonic light, and causes the reflected pulse laser light to enter the first solid-state amplifier 206 of the first solid-state laser apparatus 202 as pumping light therefor.

On the other hand, the laser control processor 12A controls the current value of the current flowing through the semiconductor laser 132 in the first semiconductor laser system 204 to alternately change on a pulse basis the wavelength of the pulse laser light PL1 output from the first solid-state laser apparatus 202 to two wavelengths in the vicinity of 1554 nm.

The pulse laser light PL1 having the wavelength of about 1554 nm and output from the first solid-state laser apparatus 202 and the pulse laser light PL4 having the wavelength of 257.6 nm and output from the first CLBO crystal 216 are summed in terms of frequency and converted in terms of wavelength by the second CLBO crystal 224 into pulse laser light having a wavelength of about 220.9 nm. Furthermore, the pulse laser light having the wavelength of about 220.9 nm and the pulse laser light having the wavelength of 1554 nm are summed in terms of frequency and converted in terms of wavelength by the third CLBO crystal 226 into the pulse laser light PL2 having the wavelength of about 193.4 nm. The pulse laser light PL2 having a wavelength that alternately changes to λ_{S} and λ_{L} on a pulse basis is then output.

The laser control processor 12A alternately controls the wavelength of the pulse laser light on a pulse basis in such a way that the wavelength approaches λ_{S}t and Art, which are wavelengths of the target two-wavelength spectrum, by performing the control in the flowchart shown in FIG. 7.

### 7.3 Others

In a system using the solid-state seeder 200, performing the control shown in the flowchart described in the second embodiment allows the wavelength of the pulse laser light to be so controlled on a pulse basis that the wavelength approaches each of the target wavelengths of the multi-wavelength spectrum.

In the system using the solid-state seeder 200, performing the control shown in the flowchart described in the third embodiment allows the wavelength of the pulse laser light to be so controlled on a pulse basis that the wavelength approaches each of the target wavelengths of the two-wavelength or multi-wavelength spectrum.

### 8. Fifth Embodiment

### 8.1 Configuration

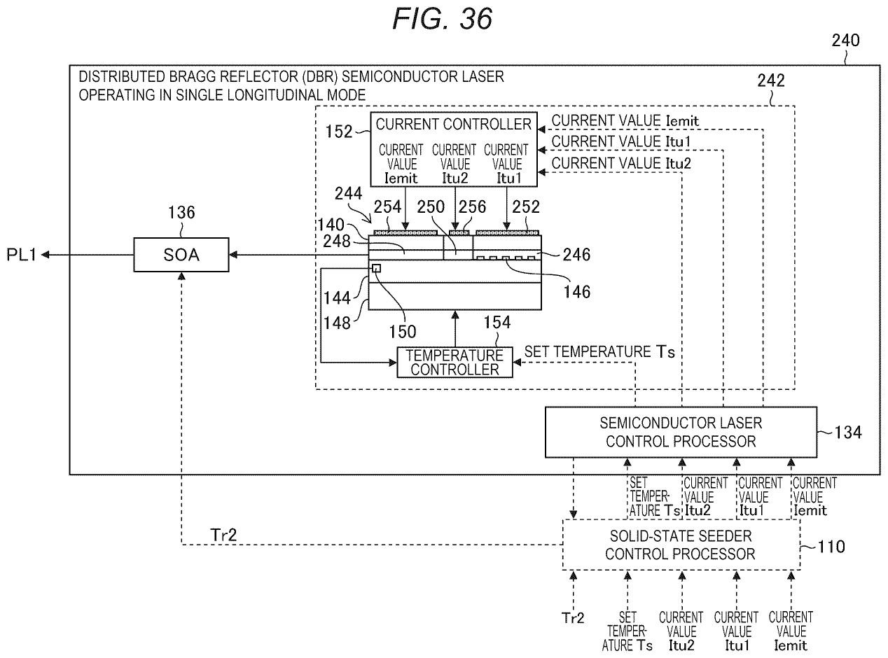

FIG. 36 schematically shows an example of the configuration of a semiconductor laser system 240. The semiconductor laser system 240 shown in FIG. 36 can be used as the semiconductor laser system 104 in FIG. 6, the first semiconductor laser system 204 in FIG. 35, or the second semiconductor laser system 210 in FIG. 35.

The semiconductor laser system 240 includes a distributed Bragg reflector (DBR) semiconductor laser 242 operating in the single longitudinal mode, and the SOA 136. The semiconductor laser 242 includes a semiconductor laser device 244. The semiconductor laser 242 in the fifth embodiment is an example of the “first semiconductor laser” in the present disclosure.

The semiconductor laser device 244 includes, between the first cladding layer 140 and the second cladding layer 144, a feedback layer 246, an active layer 248, and a phase adjustment region 250. The feedback layer 246 includes the grating 146 at the boundary between the feedback layer 246 and the second cladding layer 144. The phase adjustment region 250 is disposed between the feedback layer 246 and the active layer 248.

In the semiconductor laser device 244, electrodes 252, 254, and 256 are disposed at the first cladding layer 140. The electrodes 252, 254, and 256 are provided in correspondence with the feedback layer 246, the active layer 248, and the phase adjustment region 250, respectively.

The other configurations are the same as those in FIG. 10. Note, however, that the current controller 152 is connected to the electrodes 252, 254, and 256 via wires, and is configured to be capable of independently controlling the values of the currents flowing through the wires.

### 8.2 Operation

The oscillation center wavelength at which the semiconductor laser 242 operates can be changed by changing the set temperature Ts of the semiconductor laser device 244 and/or a current value Itu1 or Itu2 of the current flowing through the semiconductor laser device 244. The solid-state seeder control processor 110 acquires the set temperature Ts, the current values Itu1 and Itu2, and a current value Iemit from the laser control processor 12A, and transmits the acquired parameters to the semiconductor laser control processor 134. The semiconductor laser control processor 134 controls the temperature controller 154 in accordance with the set temperature Ts, and controls the current controller 152 in accordance with the current values Itu1, Itu2, and Iemit.

When the oscillation wavelength at which the semiconductor laser 242 operates is changed at high speed over a fine adjustment range, the wavelength of the CW laser light can be changed at high speed by changing the current value Itu2 of the current flowing through the phase adjustment region 250 at high speed.

When the oscillation wavelength at which the semiconductor laser 242 operates is changed at high speed over a wide range, the wavelength of the CW laser light can be changed at high speed by changing the current value Itu1 of the current flowing through the grating 146 at high speed. Note, however, that the current value Itu2 of the current flowing to the phase adjustment region 250 may also be changed because the semiconductor laser 242 cannot operate at some oscillation wavelengths.

To cause the semiconductor laser 242 to operate at an oscillation wavelength and produce desired power, the current value Iemit of the current flowing through the active layer 248 is input to the semiconductor laser 242.

The solid-state seeder control processor 110 acquires the trigger signal Tr2 from the laser control processor 12A.

When the trigger signal Tr2 is input to the solid-state seeder 200, a pulse signal is input to the SOA 136.

Causing a pulse current according to the pulse signal to flow through the semiconductor that forms the SOA 136 pulses and amplifies the CW laser light output from the semiconductor laser device 244, so that pulse laser light is output.

### 8.3 Others

The SOA 136 may receive a DC current flowing therethrough to amplify the CW laser light. In this case, the downstream solid-state amplifier 106, first solid-state amplifier 206, or second solid-state amplifier 212 is an amplifier that pulses and amplifies the CW laser light.

### 8.4 Effects and Advantages

In the distributed feedback semiconductor laser 132 shown in FIG. 10, the current value I is a common parameter that changes the wavelength and adjusts the output power, so that changing the wavelength also changes the output power. In contrast, the semiconductor laser 242 is characterized in that the output power thereof changes only by a small amount even when the current value Itu1 or Itu2 is changed, because the parameter that primarily determines the output power is the current value Iemit of the current flowing through the active layer.

Since the change in wavelength of the light from the semiconductor lasers 242 and 132 is caused by a change in the refractive index according to a change in the carrier density in the laser waveguide, the carrier density is substantially fixed to a laser-oscillation threshold carrier density in the semiconductor laser 132 when a current greater than or equal to a laser oscillation threshold flows through the semiconductor laser 132. Therefore, when a current greater than or equal to the laser oscillation threshold flows through the semiconductor laser 132, the amount of change in wavelength is relatively small even when the injection current is increased or decreased.

In contrast, in the semiconductor laser 242, the carrier density in the active layer 248 is substantially fixed to the laser-oscillation threshold carrier density when a current greater than or equal to the laser oscillation threshold flows through the semiconductor laser 242, as in the semiconductor laser 132, but the portion including the grating 146 does not have any laser gain, and neither does the phase adjustment region 250, so that the carrier density can greatly change depending on the current injected to the semiconductor laser 242. The semiconductor laser 242 can therefore change the wavelength of the light therefrom by a greater amount than the semiconductor laser 132.

### 9. Sixth Embodiment

### 9.1 Configuration

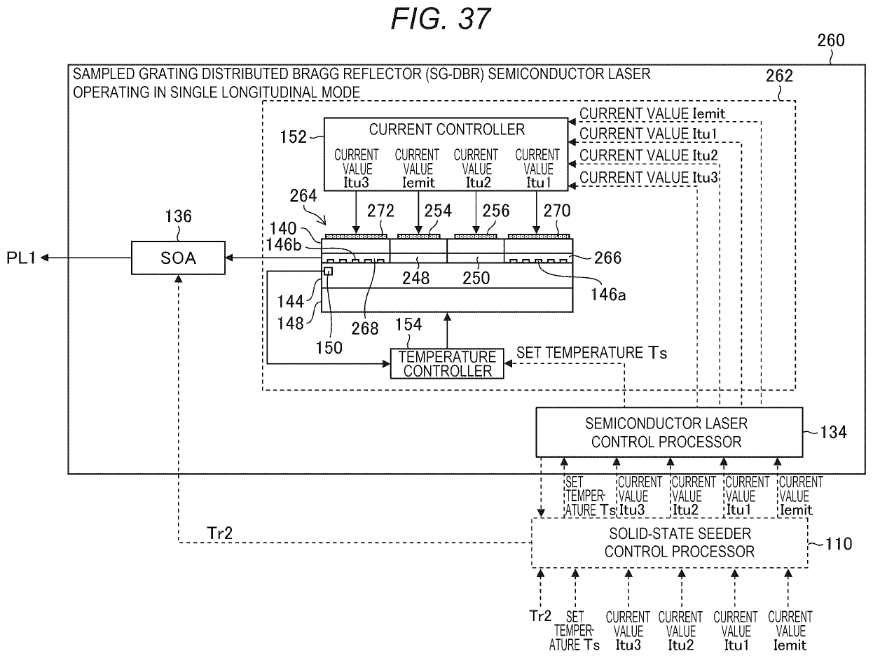

FIG. 37 schematically shows an example of the configuration of a semiconductor laser system 260. The semiconductor laser system 260 shown in FIG. 37 can be used as the semiconductor laser system 104 in FIG. 6, the first semiconductor laser system 204 in FIG. 35, or the second semiconductor laser system 210 in FIG. 35.

The semiconductor laser system 260 includes a sampled grating distributed Bragg reflector (SG-DBR) semiconductor laser 262 operating in the single longitudinal mode. The semiconductor laser 262 includes a semiconductor laser device 264. The semiconductor laser 262 in the sixth embodiment is an example of the “first semiconductor laser” in the present disclosure.

The semiconductor laser device 264 includes the active layer 248, the phase adjustment region 250, a first feedback layer 266, and a second feedback layer 268 between the first cladding layer 140 and the second cladding layer 144.

The first feedback layer 266 includes a first grating 146a at the boundary between the first feedback layer 266 and the second cladding layer 144. The second feedback layer 268 includes a second grating 146b at the boundary between the second feedback layer 268 and the second cladding layer 144. The active layer 248 and the phase adjustment region 250 are disposed between the first feedback layer 266 and the second feedback layer 268.

In the semiconductor laser device 264, electrodes 254, 256, 270, and 272 are disposed at the first cladding layer 140. The electrodes 254, 256, 270, and 272 are provided in correspondence with the active layer 248, the phase adjustment region 250, the first feedback layer 266, and the second feedback layer 268, respectively.

The other configurations are the same as those in FIG. 10. Note, however, that the current controller 152 is connected to the electrodes 254, 256, 270, and 272 via wires, and is configured to be capable of independently controlling the values of the currents flowing through the wires.

### 9.2 Operation

The oscillation center wavelength at which the semiconductor laser 262 operates can be changed by changing the set temperature Ts of the semiconductor laser device 264, the current value Itu1 or Itu2 of the current flowing through the semiconductor laser device 264, and/or a current value Itu3 of the current flowing through the semiconductor laser device 264. The solid-state seeder control processor 110 acquires the current value Itu3 from the laser control processor 12A, and transmits the acquired current value Itu3 to the semiconductor laser control processor 134. The semiconductor laser control processor 134 controls the current controller 152 in accordance with the current value Itu3.

When the oscillation wavelength at which the semiconductor laser 262 operates is changed at high speed over a fine adjustment range, the wavelength of the CW laser light can be changed at high speed by changing the current value Itu2 of the current flowing through the phase adjustment region 250 at high speed.

When the oscillation wavelength at which the semiconductor laser 262 operates is changed at high speed over a wide range, the wavelength of the CW laser light can be changed at high speed by changing the current value Itu1 of the current flowing through the first grating 146a and the current value Itu3 of the current flowing through the second grating 146b at high speed. Note, however, that the current value Itu2 of the current flowing to the phase adjustment region 250 may also be changed because the semiconductor laser 262 cannot operate at some oscillation wavelengths.

To cause the semiconductor laser 262 to operate at an oscillation wavelength and produce desired power, the current value Iemit of the current flowing through the active layer 248 is input to the semiconductor laser 262.

When the trigger signal Tr2 is input to the solid-state seeder 200, a pulse signal is input to the SOA 136.

Causing a pulse current according to the pulse signal to flow through the semiconductor that forms the SOA 136 pulses and amplifies the CW laser light output from the semiconductor laser device 264, so that pulse laser light is output.

### 9.3 Effects and Advantages

The semiconductor laser 262 is characterized in that the output power thereof changes only by a small amount even when the current value Itu1, itu2, or Itu3 is changed, because the parameter that primarily determines the output power is the current value Iemit of the current flowing through the active layer.

The semiconductor laser 262 has a configuration in which the corrugation period of the first grating 146a slightly differs from that of the second grating 146b, so that the wavelength changeable range of the semiconductor laser 262 is extremely wider than that of the semiconductor laser 242, that is, the wavelength can be changed over a range of 100 nm or wider.

### 10. Method for Manufacturing Electronic Devices

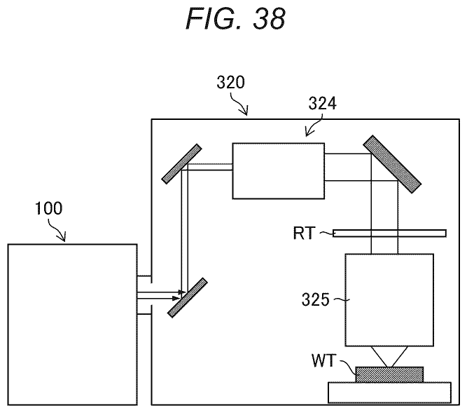

FIG. 38 schematically shows an example of the configuration of an exposure apparatus 320. In FIG. 38, the exposure apparatus 320 includes an illumination optical system 324 and a projection optical system 325. The illumination optical system 324 illuminates a reticle pattern of a reticle at the reticle stage RT with the laser light having entered the illumination optical system 324 from the laser apparatus 100. The projection optical system 325 performs reduction projection on the laser light having passed through the reticle to bring the laser light into focus on a workpiece that is not shown but is placed on a workpiece table WT. The workpiece is a photosensitive substrate onto which a photoresist has been applied, such as a semiconductor wafer. The exposure apparatus 320 synchronously moves the reticle stage RT and the workpiece table WT in parallel in directions opposite to each other to expose the workpiece to the laser light having reflected the reticle pattern. Semiconductor devices can be manufactured by transferring a device pattern onto the semiconductor wafer in the exposure step described above and then carrying out multiple other steps. The semiconductor devices are an example of the “electronic devices” in the present disclosure.

### 11. Others

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious for those skilled in the art that embodiments of the present disclosure would be appropriately combined.

The terms used throughout the present specification and the appended claims should be interpreted as non-limiting terms. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more”. Further, “at least one of A, B, and C” should be interpreted to mean any of A, B, C, A+B, A+C, B+C, and A+B+C as well as to include combinations of any thereof and any other than A, B, and C.

What is claimed is:

1. A laser apparatus comprising:
a first wavelength variable semiconductor laser configured to output first continuous-wave laser light;
a first amplifier configured to pulse and amplify the first laser light and output first pulse laser light;
a wavelength conversion system configured to convert a wavelength of the first pulse laser light and output resultant second pulse laser light;
an excimer amplifier configured to amplify the second pulse laser light and output resultant third pulse laser light;
a monitor module configured to measure a wavelength of the third pulse laser light; and
a processor configured to periodically change a target wavelength of the third pulse laser light and control a current for changing the wavelength of the laser light from the first semiconductor laser in such a way that the wavelength of the third pulse laser light becomes the target wavelength based on a measured value of the wavelength of the third pulse laser light output at the same target wavelength.

2. The laser apparatus according to claim 1,
wherein the processor is configured to control the current for changing the wavelength of the laser light from the first semiconductor laser based also on a measured value of the wavelength of the third pulse laser light output at a different target wavelength from the target wavelength in such a way that the wavelength of the third pulse laser light becomes the target wavelength.

3. The laser apparatus according to claim 2,
wherein the processor is configured to determine an approximate straight line representing a relationship between the current for changing the wavelength of the laser light from the first semiconductor laser and the wavelength of the third pulse laser light from the measured value of the wavelength of the third pulse laser light output at the same target wavelength and the measured value of the wavelength of the third pulse laser light output at the different target wavelength from the target wavelength, and control the current for changing the wavelength of the laser light from the first semiconductor laser based on the approximate straight line.

4. The laser apparatus according to claim 1,
wherein the processor is configured to control a temperature of the first semiconductor laser in such a way that an average of the current for changing the wavelength of the laser light from the first semiconductor laser has a reference current value.

5. The laser apparatus according to claim 1,
wherein the target wavelength includes two wavelengths.

6. The laser apparatus according to claim 1,
wherein the processor is configured to
calculate a target center wavelength that is an average of the periodically changing target wavelength, and
control a temperature of the first semiconductor laser based on the target center wavelength.

7. The laser apparatus according to claim 6,
wherein the processor is configured to control the temperature of the first semiconductor laser in such a way that an average of the measured values of the wavelength of the third pulse laser light becomes the target center wavelength based on a relationship between the temperature of the first semiconductor laser and the wavelength of the third pulse laser light.

8. The laser apparatus according to claim 7,
wherein the processor is configured to measure in advance the relationship between the temperature of the first semiconductor laser and the wavelength of the third pulse laser light and express the relationship by an approximate straight or curved line.

9. The laser apparatus according to claim 1,
wherein the wavelength conversion system includes a first nonlinear crystal, and
the processor is configured to
calculate a target center wavelength that is an average of the periodically changing target wavelength, and
control an actuator in such a way that the first nonlinear crystal achieves phase matching at the target center wavelength.

10. The laser apparatus according to claim 9,
wherein the actuator is a rotary stage, and
the processor is configured to control an angle of incidence of the first pulse laser light to be incident on the first nonlinear crystal.

11. The laser apparatus according to claim 9,
wherein the actuator is a heater, and
the processor is configured to control a temperature of the first nonlinear crystal.

12. The laser apparatus according to claim 1,
wherein the wavelength conversion system includes
a first nonlinear crystal, and
a rotary stage configured to rotate the nonlinear crystal, and
the processor is configured to control the rotary stage in such a way that a wavelength at which wavelength conversion efficiency is maximized becomes the target wavelength.

13. The laser apparatus according to claim 1,
wherein the wavelength conversion system is configured to output the second pulse laser light that is first harmonic light of the first pulse laser light.

14. The laser apparatus according to claim 1,
further comprising a solid-state laser apparatus configured to output fourth pulse laser light, and
the wavelength conversion system is configured to perform sum frequency operation on the first pulse laser light and the fourth pulse laser light and output the resultant second pulse laser light.

15. The laser apparatus according to claim 14,
wherein the solid-state laser apparatus includes
a second semiconductor laser configured to output second continuous-wave laser light,
a second amplifier configured to pulse and amplify the second laser light and output resultant fifth pulse laser light, and
a second nonlinear crystal configured to receive an input of the fifth pulse laser light and output second harmonic light thereof that is the fourth pulse laser light.

16. The laser apparatus according to claim 1,
wherein the first semiconductor laser is at least one of a distributed feedback semiconductor laser, a distributed Bragg reflector semiconductor laser, and a sampled grating distributed Bragg reflector semiconductor laser.

17. The laser apparatus according to claim 16,
wherein the wavelength of the laser light from the first semiconductor laser is changed by controlling a current caused to flow through a phase adjustment region of the distributed Bragg reflector semiconductor laser.

18. The laser apparatus according to claim 16,
wherein the wavelength of the laser light from the first semiconductor laser is changed by controlling a current caused to flow through a phase adjustment region of the sampled grating distributed Bragg reflector semiconductor laser.

19. A method for controlling a wavelength of laser light from a laser apparatus, the method comprising:
outputting first continuous-wave laser light from a first semiconductor laser;
pulsing and amplifying the first laser light and outputting first pulse laser light;
converting a wavelength of the first pulse laser light and outputting resultant second pulse laser light;
amplifying the second pulse laser light and outputting resultant third pulse laser light;
measuring a wavelength of the third pulse laser light;
periodically changing a target wavelength of the third pulse laser light; and
controlling a current for changing the wavelength of the laser light from the first semiconductor laser in such a way that the wavelength of the third pulse laser light becomes the target wavelength based on a measured value of the wavelength of the third pulse laser light output at the same target wavelength.

20. A method for manufacturing electronic devices, the method comprising:
generating third pulse laser light by using a laser apparatus;
outputting the third pulse laser light to an exposure apparatus; and
exposing a photosensitive substrate to the third pulse laser light in the exposure apparatus to manufacture the electronic devices,
the laser apparatus including
a first wavelength variable semiconductor laser configured to output first continuous-wave laser light,
a first amplifier configured to pulse and amplify the first laser light and output first pulse laser light,
a wavelength conversion system configured to convert a wavelength of the first pulse laser light and output resultant second pulse laser light,
an excimer amplifier configured to amplify the second pulse laser light and output the third pulse laser light,
a monitor module configured to measure a wavelength of the third pulse laser light, and
a processor configured to periodically change a target wavelength of the third pulse laser light and control a current for changing the wavelength of the laser light from the first semiconductor laser in such a way that the wavelength of the third pulse laser light becomes the target wavelength based on a measured value of the wavelength of the third pulse laser light output at the same target wavelength.
